(19) United States
(12) Patent Application Publication
(10) Pub. No.: US 2025/0293665 A1
(43) Pub. Date: Sep. 18, 2025

(54) PIEZOELECTRIC RESONATOR, PIEZOELECTRIC RESONATOR UNIT, AND PIEZOELECTRIC OSCILLATOR

(71) Applicant: Murata Manufacturing Co., Ltd., Nagaokakyo-shi (JP)

(72) Inventor: Toshio NISHIMURA, Nagaokakyo-shi (JP)

(21) Appl. No.: 19/211,421

(22) Filed: May 19, 2025

Related U.S. Application Data
(63) Continuation of application No. PCT/JP2023/028449, filed on Aug. 3, 2023.

(30) Foreign Application Priority Data
Jan. 17, 2023 (JP) 2023-004855

(51) Int. Cl. H03H 9/13; H03H 9/19

(52) U.S. Cl. CPC H03H 9/132; H03H 9/19

(57) ABSTRACT

A piezoelectric resonator that includes: a piezoelectric element having a main surface that extends in a first direction and a second direction that intersects with the first direction and having a thickness in a third direction that intersects with the first direction and the second direction; and an excitation electrode on the main surface, the excitation electrode including a first hole portion that penetrates the excitation electrode along the third direction in a central portion of the excitation electrode in the first direction, wherein, when a dimension of the excitation electrode along the first direction is defined as (Le1) and a dimension of the piezoelectric element along the third direction is defined as (Tq), 45≤Le1/Tq≤120.

### CROSS REFERENCE TO RELATED APPLICATIONS

The present application is a continuation of International application No. PCT/JP2023/028449, filed Aug. 3, 2023, which claims priority to Japanese Patent Application No. 2023-004855, filed Jan. 17, 2023, the entire contents of each of which are incorporated herein by reference.

### TECHNICAL FIELD

The present disclosure relates to a piezoelectric resonator, a piezoelectric resonator unit, and a piezoelectric oscillator.

### BACKGROUND ART

In various electronic devices, such as a mobile communication terminal, a communication base station, and a home appliance, a piezoelectric resonator is used for applications, such as a timing device, a sensor, and an oscillator. The piezoelectric resonator includes a piezoelectric element having a pair of main surfaces, and a pair of excitation electrodes provided on the pair of main surfaces of the piezoelectric element.

For example, Patent Document 1 discloses a quartz crystal resonator unit having excitation electrodes facing both main surfaces of a quartz crystal element, in which a hole is provided in the central region of the excitation electrodes to reduce mass and a vibration frequency of overtone vibration is set apart from a fundamental wave vibration.
Patent Document 1: Japanese Unexamined Patent Application Publication No. 2010-81317

### SUMMARY OF THE DISCLOSURE

However, when the thickness of the quartz crystal element is reduced to increase the frequency, in the quartz crystal resonator unit described in Patent Document 1, it is difficult to sufficiently set apart the vibration frequency of an inharmonic mode from the fundamental wave vibration of a main mode, and for example, the frequency of the inharmonic mode may be present in a range of approximately ±1% from the frequency of the main mode. Therefore, there is a problem that the influence of the inharmonic mode in the main mode cannot be sufficiently suppressed by simply setting apart the frequency of the overtone mode from the frequency of the main mode.

The present disclosure is made in view of the above circumstances, and an object of the present disclosure is to provide a piezoelectric resonator, a piezoelectric resonator unit, and a piezoelectric oscillator that can improve an electromechanical coupling coefficient.

A piezoelectric resonator according to an aspect of the present disclosure includes a piezoelectric element having a main surface that extends in a first direction and a second direction that intersects with the first direction and having a thickness in a third direction that intersects with the first direction and the second direction, and an excitation electrode provided on the main surface, in which, when a dimension of the excitation electrode along the first direction is defined as Le1 and a dimension of the piezoelectric element along the third direction is defined as Tq, a relationship of 45≤Le1/Tq≤120 is established, and a first hole portion that penetrates the excitation electrode along the third direction is formed in a central portion of the excitation electrode in the first direction.

According to the present disclosure, it is possible to provide a piezoelectric resonator, a piezoelectric resonator unit, and a piezoelectric oscillator that can improve an electromechanical coupling coefficient.

### BRIEF DESCRIPTION OF THE DRAWINGS

FIG. 1 is a cross-sectional view of a crystal oscillator according to a first embodiment.

FIG. 2 is a cross-sectional view of a quartz crystal resonator unit according to the first embodiment.

FIG. 3 is a plan view of a quartz crystal resonator according to the first embodiment.

FIG. 4 is a plan view of a first excitation electrode according to the first embodiment.

FIG. 5 is a cross-sectional view of a vibration portion according to the first embodiment.

FIG. 6 is a plan view of a first excitation electrode according to a second embodiment.

FIG. 7 is a plan view of a first excitation electrode according to a third embodiment.

FIG. 8 is a plan view of a first excitation electrode according to a fourth embodiment.

FIG. 9 is a plan view of a first excitation electrode according to a fifth embodiment.

FIG. 10 is a plan view of a first excitation electrode according to a sixth embodiment.

FIG. 11 is a plan view of a first excitation electrode according to a seventh embodiment.

FIG. 12 is a plan view of a first excitation electrode according to an eighth embodiment.

FIG. 13 is a plan view of a first excitation electrode according to a ninth embodiment.

FIG. 14 is a diagram illustrating a simulation result in a first example.

FIG. 15 is a graph illustrating an influence of a shape and a dimension of a first hole portion in the first excitation electrode of a rectangular shape.

FIG. 16 is a graph illustrating the influence of the shape and the dimension of the first hole portion in the first excitation electrode of a rectangular shape.

FIG. 17 is a graph illustrating an influence of an area ratio of the first hole portion in the first excitation electrode of a square shape.

FIG. 18 is a graph illustrating the influence of the area ratio of the first hole portion in the first excitation electrode of a square shape.

FIG. 19 is a graph illustrating an optimum condition of an area ratio of the first hole portion in the first excitation electrode of a square shape.

FIG. 20 is a graph illustrating a condition under which K of an S0 mode is increased in the first excitation electrode of a rectangular shape.

FIG. 21 is a graph illustrating a condition under which K of the S0 mode is maximum in the first excitation electrode of a rectangular shape.

FIG. 22 is a graph illustrating a condition under which K of an S1Z mode is minimum in the first excitation electrode of a rectangular shape.

FIG. 23 is a diagram illustrating a simulation result in a second example.

FIG. 24 is a graph illustrating an influence of the dimension of the first hole portion and positions of a second hole portion and a third hole portion.

FIG. 25 is a graph illustrating an influence of a shape of the first excitation electrode and the positions of the second hole portion and the third hole portion.

FIG. 26 is a graph illustrating a relationship between a short side length and a hole portion gap.

FIG. 27 is a graph illustrating an area condition under which K of the S0 mode is increased.

FIG. 28 is a graph illustrating an area condition under which K of the S0 mode is increased.

FIG. 29 is a graph illustrating an influence of a dimension of the notched first hole portion in the first excitation electrode of a rectangular shape.

FIG. 30 is a graph illustrating an influence of the dimension of the notched first hole portion in the first excitation electrode of a rectangular shape.

FIG. 31 is a graph illustrating a condition under which K of the S0 mode is maximum in the first excitation electrode of a rectangular shape.

FIG. 32 is a graph illustrating an influence of an area ratio of a hole portion in the first excitation electrode of a square shape.

FIG. 33 is a graph illustrating the influence of the area ratio of the hole portion in the first excitation electrode of a square shape.

### DESCRIPTION OF THE PREFERRED EMBODIMENTS

Embodiments of the present disclosure will be described below. In the following description of the drawings, the same or similar constituent elements are represented by the same or similar reference numerals. The drawings are examples, and the dimension and shape of each portion are schematic, and the technical scope of the present disclosure should not be interpreted as being limited to the embodiments.

Each drawing is attached with an orthogonal coordinate system consisting of an X-axis, a Y′-axis, and a Z′-axis for convenience, in order to clarify the mutual relationship between the respective drawings and to help understand the positional relationships between respective members. The X-axis, the Y′-axis, and the Z′-axis correspond to each other in each drawing. The X-axis, the Y′-axis, and the Z′-axis respectively correspond to crystallographic axes of a quartz crystal element 11, which will be described later. The X-axis corresponds to an electric axis (polar axis) of a crystal, the Y-axis corresponds to a mechanical axis of the crystal, and the Z-axis corresponds to an optical axis of the crystal, respectively. The Y′-axis and the Z′-axis are axes obtained by rotating the Y-axis and the Z-axis about the X-axis in the direction from the Y-axis to the Z-axis by 35 degrees 15 minutes±1 minute 30 seconds, respectively.

In the following description, a direction parallel to the X-axis is referred to as an “X-axis direction”, a direction parallel to the Y′-axis is referred to as a “Y′-axis direction”, and a direction parallel to the Z′-axis is referred to as a “Z′-axis direction”. In addition, the tip direction of an arrow on the X-axis, the Y′-axis, and the Z′-axis is referred to as “positive” or “+ (plus)”, and the direction opposite to the arrow is referred to as “negative” or “− (minus)”. For convenience, description is made as the +Y′-axis direction as an upward direction and the −Y′-axis direction as a downward direction, but the up-down directions of a quartz crystal resonator 10, a quartz crystal resonator unit 1, and a crystal oscillator 100 are not limited. In addition, a surface specified by the X-axis and the Z′-axis is defined as a Z′X surface, and the same applies to a surface specified by the other axis.

### First Embodiment

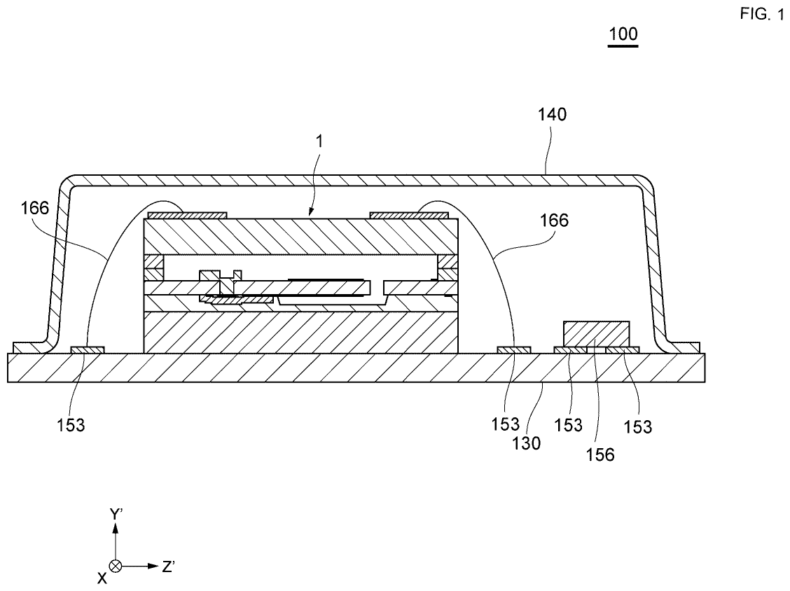

First, a schematic configuration of a crystal oscillator according to an embodiment will be described with reference to FIG. 1. FIG. 1 is a cross-sectional view of a crystal oscillator according to a first embodiment.

In the following description, as the piezoelectric oscillator, a crystal oscillator (XO) including a quartz crystal resonator unit is taken as an example. In addition, as a piezoelectric resonator unit, a quartz crystal resonator unit including a quartz crystal resonator will be taken as an example for description. In addition, as the piezoelectric resonator, a quartz crystal resonator including a quartz crystal element will be described as an example. The quartz crystal element is a type of piezoelectric body (piezoelectric element) that vibrates according to an applied voltage. The piezoelectric oscillator is not limited to a quartz crystal resonator unit, and another piezoelectric body, such as ceramic may be used. Similarly, the piezoelectric resonator unit is not limited to a quartz crystal resonator unit, and another piezoelectric body, such as ceramic may be used. Similarly, the piezoelectric resonator is not limited to a quartz crystal resonator, and another piezoelectric body, such as ceramic may be used.

As illustrated in FIG. 1, the crystal oscillator 100 includes the quartz crystal resonator unit 1, a mounting substrate 130, a lid 140, and an electronic component 156.

The quartz crystal resonator unit 1 and the electronic component 156 are housed in a space formed between the mounting substrate 130 and the lid 140. The space formed by the mounting substrate 130 and the lid 140 is, for example, airtightly sealed. The space may be airtightly sealed in a vacuum state or may be airtightly sealed in a state filled with a gas such as an inert gas.

The mounting substrate 130 is a circuit substrate of a flat plate shape. The mounting substrate 130 is configured by including, for example, a glass epoxy plate and a wiring layer patterned on the glass epoxy plate.

The quartz crystal resonator unit 1 is provided on one surface (upper surface in FIG. 1) of the mounting substrate 130. More specifically, the quartz crystal resonator unit 1 is electrically connected to a wiring layer of the mounting substrate 130 by a bonding wire 166. In addition, the quartz crystal resonator unit 1 and the wiring layer of the mounting substrate 130 are bonded by solder 153. As a result, the quartz crystal resonator unit 1 is sealed in a space formed between the mounting substrate 130 and the lid 140.

The lid 140 includes a bottomed cavity that is open on one side (lower side in FIG. 1). In other words, the lid 140 includes a top wall portion of a flat plate shape, a side wall portion that extends from the outer edge of the top wall portion toward the mounting substrate 130, and a flange portion that extends to an outer side portion from the tip of the side wall portion. The flange portion is bonded to one surface (upper surface in FIG. 1) of the mounting substrate 130. As a result, the quartz crystal resonator unit 1 bonded to the mounting substrate 130 is housed inside the lid 140. The lid 140 is made of a metal material, and is formed, for example, by drawing a metal plate.

The electronic component 156 is provided on one surface (upper surface in FIG. 1) of the mounting substrate 130. More specifically, the wiring layer of the mounting substrate 130 and the electronic component 156 are bonded by the solder 153. As a result, the electronic component 156 is mounted on the mounting substrate 130.

The electronic component 156 is electrically connected to the quartz crystal resonator unit 1 through the wiring layer of the mounting substrate 130. The electronic component 156 is configured by including, for example, a capacitor, an IC chip, or the like. The electronic component 156 is, for example, a portion of an oscillation circuit that oscillates the quartz crystal resonator unit 1, a portion of a temperature compensation circuit that compensates for the temperature characteristics of the quartz crystal resonator unit 1, or the like. When the electronic component 156 includes the temperature compensation circuit, the crystal oscillator 100 may be called a temperature compensated crystal oscillator (TCXO).

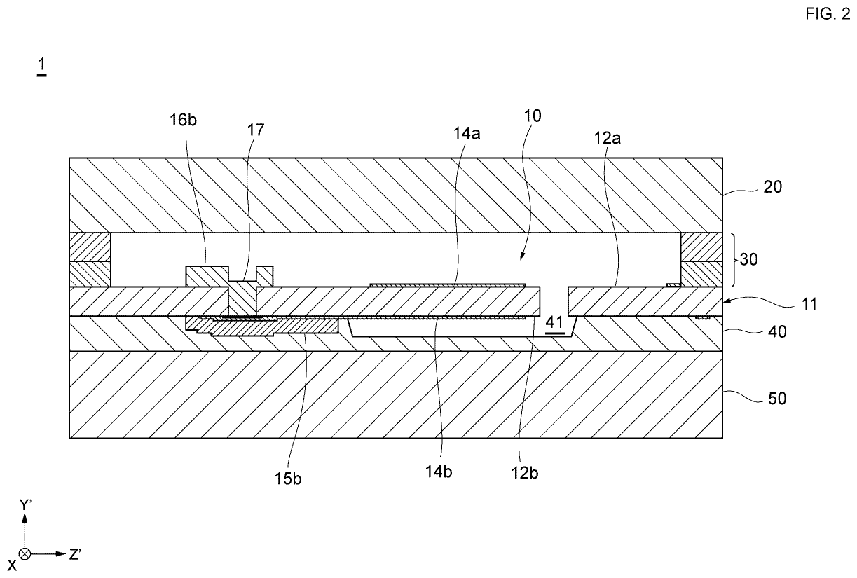

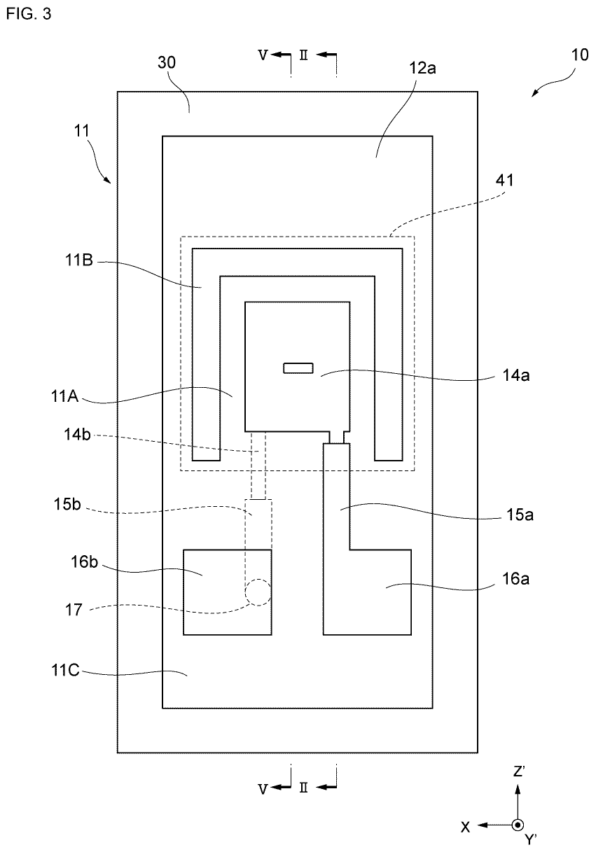

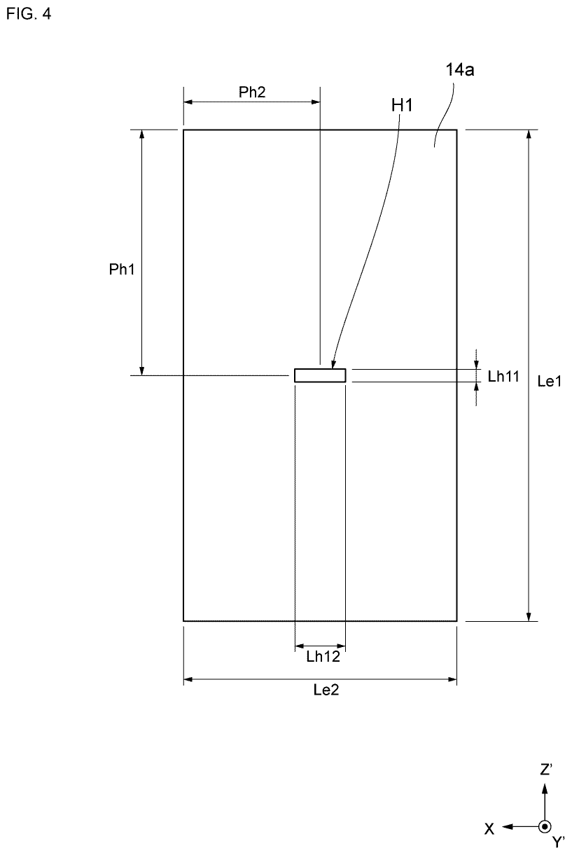

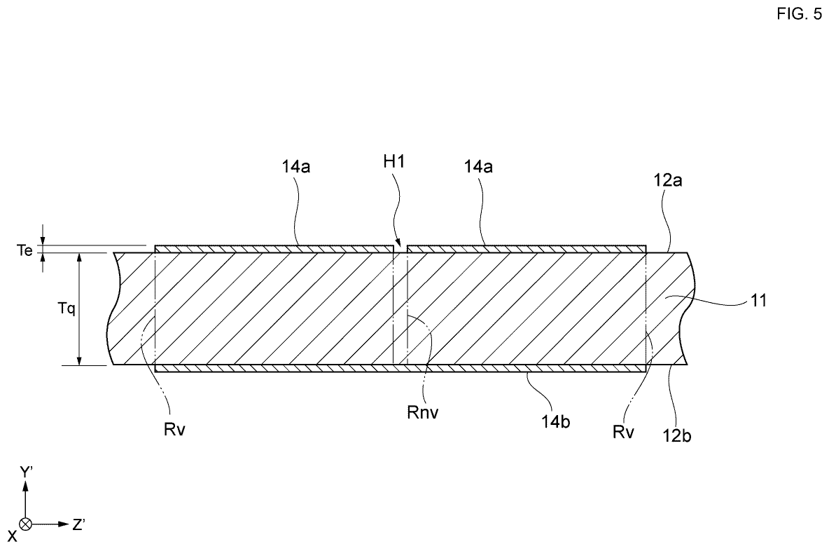

Next, the schematic configuration of the quartz crystal resonator unit according to an embodiment will be described with reference to FIGS. 2 to 5. FIG. 2 is a cross-sectional view of the quartz crystal resonator unit according to the first embodiment. FIG. 3 is a plan view of the quartz crystal resonator according to the first embodiment. FIG. 4 is a plan view of a first excitation electrode according to the first embodiment. FIG. 5 is a cross-sectional view of a vibration portion according to the first embodiment. FIG. 2 illustrates a cross section parallel to a Y′Z′ surface along line II-II illustrated in FIG. 3. FIG. 5 illustrates a cross section parallel to a Y′Z′ surface along line V-V illustrated in FIG. 3.

The Z′-axis direction corresponds to an example of a “first direction”, the X-axis direction corresponds to an example of a “second direction”, and the Y′-axis direction corresponds to an example of a “third direction”. However, the first direction, the second direction, and the third direction are not limited to the above. For example, the X-axis direction may be the first direction and the Z′-axis direction may be the second direction.

The quartz crystal resonator unit 1 includes the quartz crystal resonator 10, an upper lid 20, a bonding portion 30, an insulating layer 40, and a support substrate 50. The insulating layer 40 and the support substrate 50 correspond to an example of a “first lid member”, and the upper lid 20 corresponds to an example of a “second lid member”.

The quartz crystal resonator 10 is an electromechanical energy conversion element that mutually converts electric energy and mechanical energy by a piezoelectric effect. The frequency of the main mode of the quartz crystal resonator 10 is, for example, in the GHz band, for example, approximately 1.0 GHz to 2.0 GHz, for example, approximately 1.45 GHz. The frequency of the inharmonic mode of the quartz crystal resonator 10 is, for example, within a range of approximately 1% of the frequency of the main mode. The quartz crystal resonator 10 includes the quartz crystal element 11 of a flake shape, a first excitation electrode 14a and a second excitation electrode 14b constituting a pair of excitation electrodes, a first extended electrode 15a and a second extended electrode 15b constituting a pair of extended electrodes, a first connection electrode 16a and a second connection electrode 16b constituting a pair of connection electrodes, and a via electrode 17.

The quartz crystal element 11 has an upper surface 12a and a lower surface 12b that face each other. The upper surface 12a is positioned on the side facing the upper lid 20. The lower surface 12b is positioned on the side facing the support substrate 50. The upper surface 12a and the lower surface 12b correspond to a pair of main surfaces of the quartz crystal element 11.

The quartz crystal element 11 is, for example, an AT-cut type quartz crystal. The AT-cut type quartz crystal is formed such that an XZ′ surface is the main surface and the thickness is in the direction parallel to the Y′-axis. As an example, when the upper surface 12a is viewed in plan view (hereinafter, simply referred to as “in plan view”), the shape of the quartz crystal element 11 (hereinafter, referred to as a “planar shape”) is a rectangular shape having a long side that extends in the Z′-axis direction and a short side that extends in the X-axis direction. In addition, the quartz crystal element 11 has a thickness in the Y′-axis direction. As an example, the quartz crystal element 11 has a flat plate shape having a uniform thickness.

The planar shape of the quartz crystal element is not limited to the above, and may be a rectangular shape in which a short side extends in the Z′-axis direction and a long side extends in the X-axis direction. The planar shape of the quartz crystal element may be a polygonal shape, a circular shape, an elliptical shape, or a combination thereof. In addition, the quartz crystal element is not limited to a flat plate shape, and the quartz crystal element may have a so-called mesa structure in which the thickness of the portion that overlaps the first excitation electrode 14a and the second excitation electrode 14b is larger than the thickness of the surroundings. The quartz crystal element may have a so-called inverted mesa structure in which the thickness of the portion that overlaps the first excitation electrode 14a and the second excitation electrode 14b is smaller than the thickness of the surroundings. When the thickness of the quartz crystal element is partially changed, it may be a convex structure in which the change amount in the thickness changes continuously, or a bevel structure in which the change amount in the thickness changes discontinuously.

The axes obtained by rotating the Y-axis and the Z-axis among the X-axis, the Y-axis, and the Z-axis, which are crystallographic axes of an artificial crystal (synthetic quartz crystal), by 35 degrees 15 minutes±1 minute and 30 seconds in the direction from the Y-axis to the Z-axis around the X-axis are defined as the Y′-axis and the Z′-axis, respectively, and the quartz crystal element 11 of an AT-cut type is obtained by cutting out the XZ′ surface as a main surface.

The quartz crystal resonator 10 using the quartz crystal element 11 of an AT-cut type has high frequency stability in a wide temperature range. In addition, the AT-cut quartz crystal resonator has good time change characteristics and can be manufactured at low cost. Furthermore, the AT-cut quartz crystal resonator uses a thickness shear vibration mode as a main vibration.

The cut-angles of the quartz crystal element are not limited to the above. The rotation angles of the Y′-axis and the Z′-axis in the quartz crystal element 11 of an AT-cut type may be inclined in a range of −5 degrees to +15 degrees from 35 degrees 15 minutes. In addition, as the cut-angles of the quartz crystal element, a different cut other than the AT cut, for example, a BT cut, a GT cut, an SC cut, or the like may be applied.

The quartz crystal element 11 includes a vibration portion 11A, a cavity 11B, and a holding portion 11C.

As described above, the vibration portion 11A of the quartz crystal element 11 vibrates at a predetermined resonant frequency with the thickness shear vibration mode as the main vibration. The cavity 11B of the quartz crystal element 11 is an opening formed to surround the periphery of the vibration portion 11A when the upper surface 12a is viewed in plan view. The cavity 11B penetrates the quartz crystal element 11 in the thickness direction parallel to the Z′-axis direction and communicates with a hollow portion 41, which will be described later. The cavity 11B is formed such that the vibration portion 11A and the holding portion 11C are separated from each other by, for example, approximately 10 μm. The holding portion 11C of the quartz crystal element 11 holds an end portion (lower end portion in FIG. 2) of the vibration portion 11A. The holding portion 11C is connected to, for example, the side of the vibration portion 11A on the negative direction side of the X-axis.

The first excitation electrode 14a and the second excitation electrode 14b apply an alternating voltage to the vibration portion 11A to excite the vibration portion 11A. The first excitation electrode 14a and the second excitation electrode 14b are provided in the central portion of the vibration portion 11A. The first excitation electrode 14a is provided on the upper surface 12a, and the second excitation electrode 14b is provided on the lower surface 12b. The first excitation electrode 14a and the second excitation electrode 14b face each other in the Y′-axis direction with the vibration portion 11A interposed therebetween.

The planar shape of the first excitation electrode 14a is a rectangular shape having a long side that extends in the Z′-axis direction and a short side that extends in the X-axis direction. In addition, the first excitation electrode 14a has a thickness in the Y′-axis direction. The second excitation electrode 14b also has the same shape.

The planar shape of the first excitation electrode and the second excitation electrode are not limited to the above. The planar shape of the first excitation electrode and the second excitation electrode may be a rectangular shape having a long side that extends in the X-axis direction. In addition, the planar shape of the first excitation electrode and the second excitation electrode may be a square shape, a polygonal shape, a circular shape, an elliptical shape, or a combination thereof.

As illustrated in FIGS. 4 and 5, a hole portion H1 that penetrates the first excitation electrode 14a along the Y′-axis direction is formed in the central portion of the first excitation electrode 14a in plan view. The hole portion H1 corresponds to an example of a “first hole portion”. In plan view, the central portion of the hole portion H1 is positioned at the central portion of the first excitation electrode 14a in the Z′-axis direction and is positioned in the central portion of the first excitation electrode 14a in the X-axis direction. In other words, the hole portion H1 is formed such that the geometric center thereof coincides with the geometric center of the first excitation electrode 14a. The hole portion H1 is separated from the end portions along the long side and the short side of the first excitation electrode 14a. The planar shape of the hole portion H1 is a rectangular shape having a short side that extends in the Z′-axis direction and a long side that extends in the X-axis direction. In other words, the longitudinal direction of the hole portion H1 is a direction orthogonal to the longitudinal direction of the first excitation electrode 14a.

The hole portion may be separated from the central portion of the first excitation electrode 14a in the X-axis direction as long as the hole portion is positioned in the central portion of the first excitation electrode 14a in the Z′-axis direction.

The planar shape of the hole portion is not limited to the above. The planar shape of the hole portion may be a polygonal shape, a circular shape, an elliptical shape, or a combination thereof. In addition, the hole portion H1 may include a plurality of small holes, and the shape of the plurality of small holes is not particularly limited.

The hole portion is not formed in the second excitation electrode 14b, and the hole portion H1 faces the second excitation electrode 14b in the Y′-axis direction. The quartz crystal element 11 is excited in a vibration region Rv in which the first excitation electrode 14a and the second excitation electrode 14b overlap in the Y′-axis direction, and the quartz crystal element 11 is not excited in a non-vibration region Rnv in which the hole portion H1 is overlapped in the Y′-axis direction.

Similarly to the first excitation electrode, a hole portion may be formed also in the central portion of the second excitation electrode. In this case, it is preferable that the planar shape and the area of the hole portion formed in the second excitation electrode are substantially the same as the planar shape and the area of the hole portion formed in the first excitation electrode. In addition, it is preferable that the end portion of the hole portion formed in the second excitation electrode and the end portion of the hole portion formed in the first excitation electrode overlap each other in the Y′-axis direction. This is to suppress the generation of spurious vibration due to the disturbance in the direction and the magnitude of the voltage applied to the quartz crystal element 11.

As illustrated in FIGS. 4 and 5, the dimension of the quartz crystal element 11 along the Y′-axis direction is defined as a crystal thickness Tq. A dimension of the first excitation electrode 14a along the Z′-axis direction is defined as a first electrode length Le1, a dimension of the first excitation electrode 14a along the X-axis direction is defined as a second electrode length Le2, and a dimension of the first excitation electrode 14a along the Y′-axis direction is defined as an electrode thickness Te. A dimension of the hole portion H1 along the Z′-axis direction is defined as a first hole portion length Lh11, and a dimension of the hole portion H1 along the X-axis direction is defined as a second hole portion length Lh12. The distance of the geometric center of the hole portion H1 from the short side of the first excitation electrode 14a along the Z′-axis direction is defined as a first hole portion distance Ph1. The distance of the geometric center of the hole portion H1 from the long side of the first excitation electrode 14a along the X-axis direction is defined as a second hole portion distance Ph2.

The crystal thickness Tq is, for example, in a range of 0.5 μm to 3 μm, for example, approximately 1 μm. The first electrode length Le1 is, for example, approximately 120 μm, the second electrode length Le2 is, for example, approximately 50 μm, and the electrode thickness is, for example, approximately 0.05 μm.

A relationship of 45≤Le1/Tq≤120 is established between the crystal thickness Tq and the first electrode length Le1. When the relationship of 45≤Le1/Tq is established, the oscillation condition is easily satisfied because the equivalent series resistance decreases, and it is difficult to be affected by the parasitic capacitance because the equivalent series capacitance increases. It is further preferable that a relationship of 60≤Le1/Tq≤120 is established. Since the relationship of Le1/Tq≤120 is established, the frequency of the inharmonic mode, in which vibration antinodes are disposed side by side in the Z′-axis direction, (hereinafter, referred to as a “first direction inharmonic mode”) can be suppressed from excessively approaching the frequency of the main mode.

The relationship of 10≤Le2/Tq≤45 is established between the crystal thickness Tq and the second electrode length Le2. When 10≤Le2/Tq is established, the oscillation condition is easily satisfied because the equivalent series resistance decreases, and it is difficult to be affected by the parasitic capacitance because the equivalent series capacitance increases. Since Le2/Tq≤45 is established, the frequency of the inharmonic mode, in which vibration antinodes are disposed side by side in the X-axis direction, (hereinafter, referred to as a “second direction inharmonic mode”) is sufficiently far from the frequency of the main mode, so that the influence of the second direction inharmonic mode on the main mode can be reduced although the second direction inharmonic mode is not suppressed.

The first hole portion length Lh11 is, for example, approximately 5 μm, and the second hole portion length Lh12 is, for example, approximately 15 μm. The first hole portion distance Ph1 is, for example, approximately a half±10% of the first electrode length Le1. That is, the relationship of 0.9×{(½)×Le1}≤Ph1≤1.1×{(½)×Le1} is established. The second hole portion distance Ph2 is, for example, approximately a half±10% of the second electrode length Le2. That is, the relationship of 0.9×{(½)×Le2}≤Ph2≤1.1×{(½)×Le2} is established.

However, the relationship among the first electrode length Le1, the second electrode length Le2, the first hole portion distance Ph1, and the second hole portion distance Ph2 is not limited to the above. For example, when the relationship of 45≤Le1/Tq≤120 and 10≤Le2/Tq≤45 is established, assuming that the relationship of 0.9×{(½)×Le1}≤ Ph1≤1.1×{(½)×Le1} is established, then the relationship of 0.9×{(½)×Le2}≤Ph2≤1.1×{(½)×Le2} need not be necessarily established. That is, in such a case, the relationship of Ph2<0.9×{(½)×Le2} or 1.1×{(½)×Le2}<Ph2 may be established.

On the other hand, when the relationship of 10≤Le1/Tq≤45 and 45≤Le2/Tq≤ 120 is established, assuming that the relationship of 0.9×{(½)×Le2}≤Ph2≤1.1×{(½)×Le2} is established, then the relationship of Ph1<0.9×{(½)×Le1} or 1.1×{(½)×Le1}<Ph1 may be established.

When the relationship of 45≤Le1/Tq≤120 and 45≤Le2/Tq≤120 is established, at least one of the relationship of 0.9×{(½)×Le1}≤Ph1≤1.1×{(½)×Le1} and the relationship 0.9×{(½)×Le2}≤Ph2≤1.1×{(½)×Le2} may be established, and preferably, both the relationships are established.

The first extended electrode 15a electrically connects the first excitation electrode 14a to the first connection electrode 16a, and the second extended electrode 15b electrically connects the second excitation electrode 14b to the second connection electrode 16b. The first extended electrode 15a and the second extended electrode 15b are provided from the vibration portion 11A to the holding portion 11C. The first extended electrode 15a is provided on the upper surface 12a of the quartz crystal element 11, and the second extended electrode 15b is provided on the lower surface 12b of the quartz crystal element 11. The first extended electrode 15a is electrically connected to the first excitation electrode 14a in the vibration portion 11A and electrically connected to the first connection electrode 16a in the holding portion 11C. The second extended electrode 15b is electrically connected to the second excitation electrode 14b in the vibration portion 11A and electrically connected to the second connection electrode 16b in the holding portion 11C.

The first connection electrode 16a and the second connection electrode 16b are terminals for electrically connecting to an outer electrode provided on the upper lid 20. The first connection electrode 16a and the second connection electrode 16b are provided on the holding portion 11C. In addition, the first connection electrode 16a and the second connection electrode 16b are provided on the upper surface 12a of the quartz crystal element 11.

The materials of the first excitation electrode 14a, the second excitation electrode 14b, the first extended electrode 15a, the second extended electrode 15b, the first connection electrode 16a, and the second connection electrode 16b are, for example, aluminum (Al), molybdenum (Mo), gold (Au), or an aluminum-copper alloy (AlCu) having aluminum as a main component. The electrodes may be a single layer film or a multilayer film. In a case of a multilayer film, the first excitation electrode 14a and the second excitation electrode 14b may include, for example, a base layer having good close contact ability to crystal and a surface property having good chemical stability. The base layer is, for example, a chromium (Cr) layer or a titanium (Ti) layer, and the surface layer is, for example, a gold (Au) layer.

The via electrode 17 electrically connects the second extended electrode 15b to the second connection electrode 16b. The via electrode 17 is provided to penetrate the quartz crystal element 11 from the upper surface 12a to the lower surface 12b. The material of the via electrode 17 is, for example, aluminum (Al), and the thickness of the via electrode 17 is, for example, 1.0 μm. The material of the via electrode 17 may be, for example, copper (Cu) or an aluminum-copper alloy (AlCu) having aluminum as a main component. The thickness of the via electrode 17 is, for example, within a range of 0.5 μm to 3.0 μm.

The upper lid 20 is a flat plate-shaped member. The dimension of the upper lid 20 in plan view is the same or substantially the same as the dimension of the quartz crystal resonator 10 (the quartz crystal element 11). The thickness of the upper lid 20 is, for example, within a range of 100 μm to 200 μm.

The material of the upper lid 20 is, for example, crystal. Accordingly, it is possible to reduce the stress due to the difference in thermal expansion coefficients between the bonding portion 30 and the quartz crystal resonator 10.

The upper lid 20 is not limited to being a crystal plate, and may be, for example, a ceramic plate, a glass plate, or the like. When the upper lid is provided with a heat-resistant ceramic plate, it is possible to suppress deformation of the quartz crystal resonator 10 and generation of thermal stress due to a thermal history. In addition, when the upper lid is provided with a transparent glass plate, after the quartz crystal resonator 10 is sealed, the first excitation electrode 14a can be irradiated with a laser from the outside to adjust the resonant frequency.

In addition, the upper lid 20 may have conductivity. As the upper lid 20 is configured with the conductive material, the upper lid 20 is provided with an electromagnetic shield function of reducing the entry and exit of electromagnetic waves into the inner space. In this case, it is preferable that the upper lid 20 is provided with 42 Alloy that is an alloy including iron (Fe) and nickel (Ni), Kovar that is an Fe—Ni—Co-based alloy including iron (Fe), nickel (Ni), and cobalt (Co), or the like. Since the thermal expansion coefficient of the Fe—Ni—Co-based alloy near room temperature coincides with that of glass or ceramic in a wide temperature range, the generation of thermal stress can be suppressed.

The bonding portion 30 bonds the quartz crystal resonator 10 and the upper lid 20. A space is formed by the upper lid 20 and the quartz crystal resonator 10 bonded to each other. The space forms a portion of a vibration space of the vibration portion 11A. The bonding portion 30 is provided along the entire periphery of each of the upper lid 20 and the quartz crystal resonator 10. Specifically, the bonding portion 30 is provided between the lower surface of the upper lid 20 and the upper surface 12a of the quartz crystal element 11. In plan view, the bonding portion 30 is provided in a frame shape. The width of the bonding portion 30, that is, the difference between the outer periphery and the inner periphery is, for example, approximately 20 μm.

The bonding portion 30 is provided by, for example, low-melting glass, such as lead borate or tin phosphate. The bonding portion 30 may be provided by, for example, an organic adhesive including an epoxy, vinyl, acrylic, urethane, or silicon-based resin, a silicon-based adhesive including water glass or the like, a calcium-based adhesive including cement or the like, or metal bonding of gold tin (Au—Sn)-based eutectic alloy or the like. The quartz crystal resonator 10 and the upper lid 20 may be bonded by seam welding.

The insulating layer 40 includes the hollow portion 41 formed at a portion corresponding to the vibration portion 11A of the quartz crystal resonator 10. The hollow portion 41 has a recessed shape, and forms a space between the hollow portion 41 and the second excitation electrode 14b provided on the lower surface 12b of the quartz crystal element 11.

The insulating layer 40 bonds the quartz crystal resonator 10 and the support substrate 50. More specifically, the insulating layer 40 is formed on the lower surface of the quartz crystal resonator 10 and bonds the upper surface of the support substrate 50 and the lower surface 12b of the quartz crystal element 11.

The material of the insulating layer 40 is, for example, a silicon oxide film including silicon dioxide (SiO₂) or the like. Accordingly, it is possible to reduce the stress due to the difference in thermal expansion coefficient from the quartz crystal resonator 10 and the stress due to the difference in thermal expansion coefficient from the support substrate 50.

The thickness of the insulating layer 40 is preferably 0.5 μm or more, for example, within a range of 1 μm to 1.5 μm. In this case, the depth of the hollow portion 41 in the Y′-axis direction is, for example, within a range of 0.2 μm to 0.5 μm.

The material of the insulating layer 40 is not limited to the silicon oxide film, and may be a silicon nitride film, a silicon oxynitride film, or various adhesives.

The support substrate 50 is configured to support the quartz crystal resonator 10 and the insulating layer 40. Specifically, the holding portion 11C of the quartz crystal element 11 is supported via the insulating layer 40.

The support substrate 50 is, for example, a flat plate-shaped substrate. The dimension of the support substrate 50 in plan view is the same or substantially the same as the dimension of the quartz crystal resonator 10 (the quartz crystal element 11). The thickness of the support substrate 50 along the Y′-axis direction is, for example, within a range of 50 μm to 500 μm.

The material of the support substrate 50 is, for example, crystal. Accordingly, it is possible to reduce the stress due to the difference in thermal expansion coefficients between the quartz crystal resonator 10 and the insulating layer 40.

The support substrate 50 is not limited to a case of a crystal plate, and may be, for example, a ceramic plate, a silicon substrate, a glass plate, or the like. When the support substrate 50 is provided of a heat-resistant ceramic plate, deformation of the quartz crystal resonator 10 due to a thermal history can be suppressed.

As described above, when the dimension of the first excitation electrode 14a along the first direction is defined as Le1, the thickness of the quartz crystal element 11 is defined as Tq, and the relationship of 45≤Le1/Tq≤120 is established, a through hole is formed in the central portion of the first excitation electrode 14a in the first direction. According to this, as will be described later, the electromechanical coupling coefficient in the inharmonic mode in which vibration antinodes are disposed side by side in the first direction can be decreased, and the electromechanical coupling coefficient in the main mode increases.

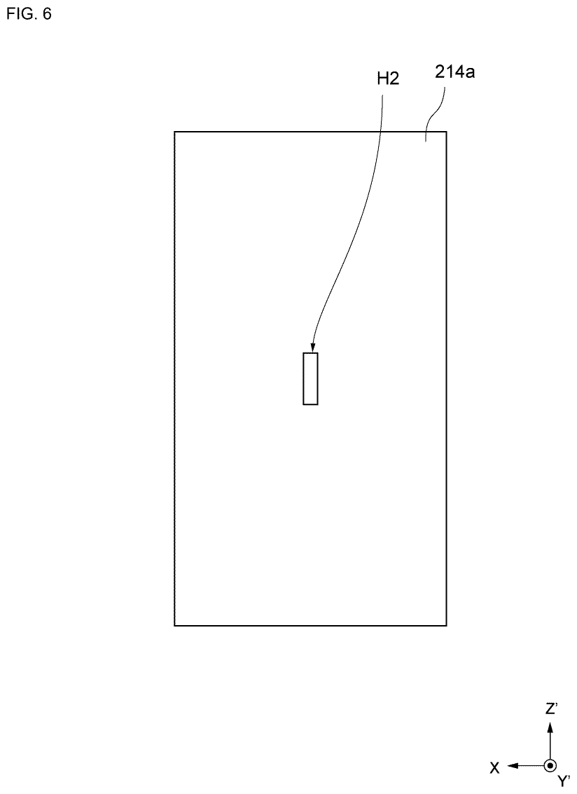

Next, configurations of first excitation electrodes 214a to 914a according to second to ninth embodiments will be described with reference to FIGS. 6 to 13. FIGS. 6 to 13 are plan views of the first excitation electrodes 214a to 914a according to the second to ninth embodiments. In the following embodiment, the description of matters in common with the first embodiment will be omitted, and only the different points will be described. In particular, the same operation and effect due to the same configuration will not be sequentially referred to.

### Second Embodiment

The planar shape of a hole portion H2 formed in the first excitation electrode 214a illustrated in FIG. 6 is a rectangular shape having a long side that extends in the Z′-axis direction and a short side that extends in the X-axis direction. In other words, the longitudinal direction of the hole portion H2 is a direction parallel to the longitudinal direction of the first excitation electrode 214a.

### Third Embodiment

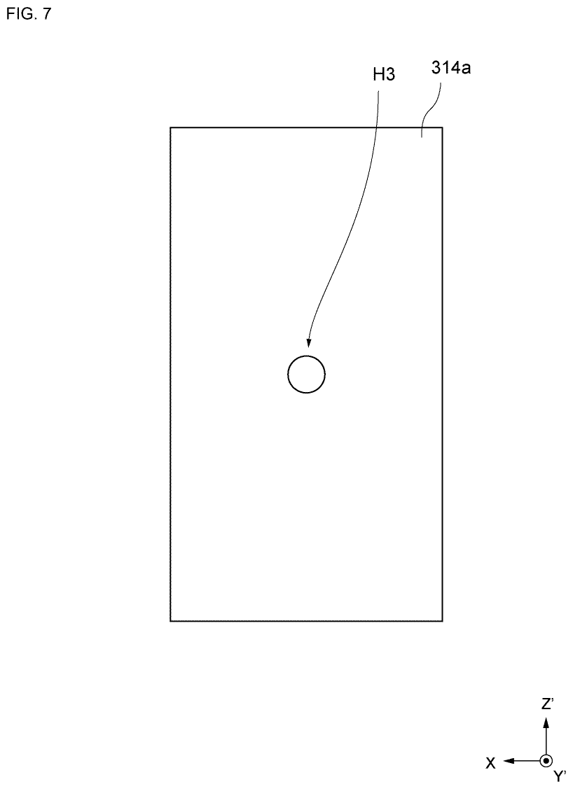

The planar shape of a hole portion H3 formed in the first excitation electrode 314a illustrated in FIG. 7 is a circular shape.

### Fourth Embodiment

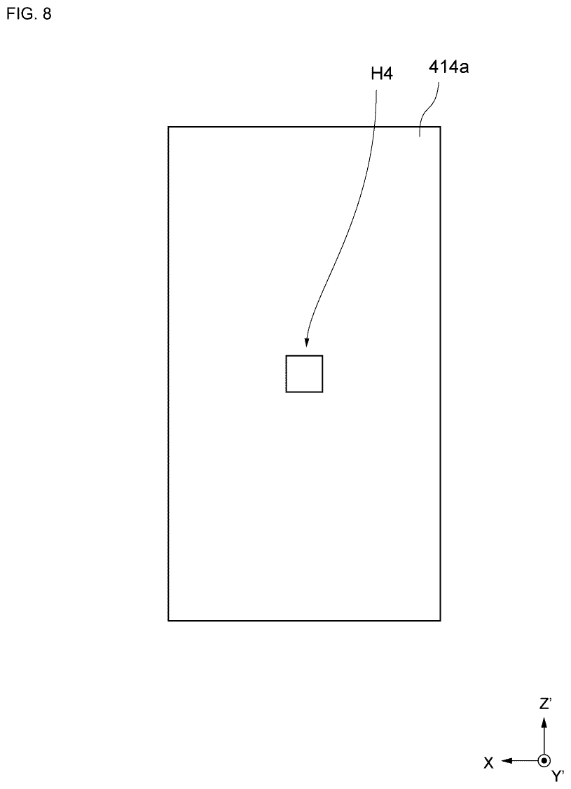

The planar shape of a hole portion H4 formed in the first excitation electrode 414a illustrated in FIG. 8 is a square shape having a side that extends in the Z′-axis direction and a side that extends in the X-axis direction.

### Fifth Embodiment

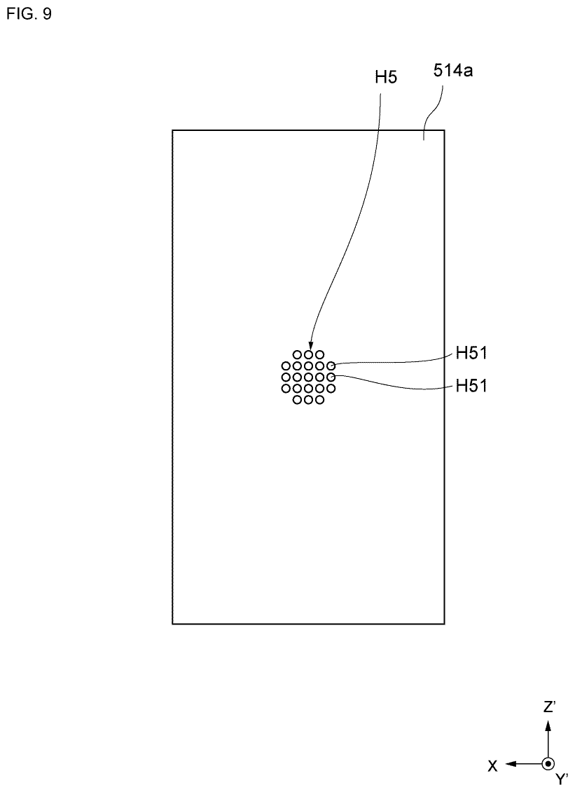

A hole portion H5 formed in the first excitation electrode 514a illustrated in FIG. 9 includes a plurality of small holes H51. The planar shape of the plurality of small holes H51 is, for example, a circular shape having a radius of approximately 1 μm. The plurality of small holes H51 are disposed side by side in a grid shape in the Z′-axis direction and the X-axis direction. The distance between the centers of the adjacent small holes H51 is, for example, approximately 3 μm. The number of the plurality of small holes H51 is, for example, 21.

The planar shape, the area, and the disposition of the plurality of small holes are not limited to the above. The planar shape of the plurality of small holes may be, for example, a rectangular shape, a square shape, another polygonal shape, a circular shape, an elliptical shape, or a combination thereof. The plurality of small holes may include different types of small holes having different planar shapes from each other. The plurality of small holes may include different types of small holes having different areas from each other. The disposition of the plurality of small holes may be, for example, in a zigzag manner or in a concentric circle shape.

### Sixth Embodiment

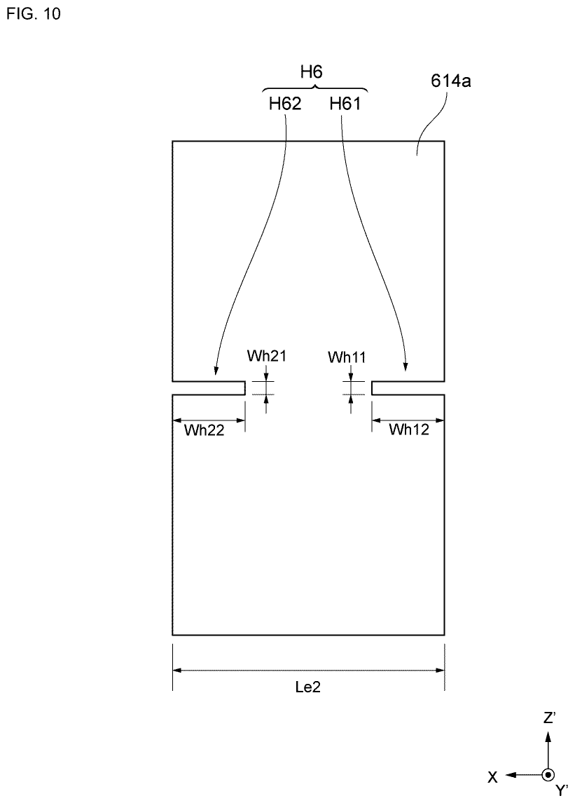

A hole portion H6 formed in the first excitation electrode 614a illustrated in FIG. 10 is a notched cavity that is open in the X-axis direction at an end portion along the long side of the first excitation electrode 614a. The hole portion H6 includes a notched portion H61 formed at the end portion of the first excitation electrode 614a on the negative direction side of the X-axis direction, and a notched portion H62 formed at the end portion of the first excitation electrode 614a on the positive direction side of the X-axis direction.

The notched portion H61 and the notched portion H62 are spaced apart from each other and disposed side by side in the X-axis direction. The geometric centers of the notched portions H61 and H62 are positioned on the center line that extends in the X-axis direction through the geometric center of the first excitation electrode 614a. The planar shape of the notched portions H61 and H62 is a rectangular shape having a short side that extends in the Z′-axis direction and a long side that extends in the X-axis direction. The dimension of the notched portion H61 along the Z′-axis direction is defined as a hole portion length Wh11, the dimension of the notched portion H61 along the X-axis direction is defined as a hole portion length Wh12, the dimension of the notched portion H62 along the Z′-axis direction is defined as a hole portion length Wh21, and the dimension of the notched portion H62 along the X-axis direction is defined as a hole portion length Wh22. Since the notched portions H61 and H62 have a rectangular shape with the X-axis direction as the longitudinal direction, the hole portion length Wh11 is smaller than the hole portion length Wh12 (Wh11<Wh12), and the hole portion length Wh21 is smaller than the hole portion length Wh22 (Wh21<Wh22). In addition, since the notched portions H61 and H62 are separated from each other, the sum of the hole portion length Wh12 and the hole portion length Wh22 is smaller than the second electrode length Le2 (Wh12+Wh22<Le2). As an example, the hole portion length Wh11 is substantially equal to the hole portion length Wh21 (Wh11=Wh21), and the hole portion length Wh12 is substantially equal to the hole portion length Wh22 (Wh12=Wh22). In other words, the area of the notched portion H61 is substantially equal to the area of the notched portion H62.

The positions, the planar shapes, and the areas of the two notched portions are not limited to the above. The geometric centers of the two notched portions may be separated from the center line that extends in the X-axis direction of the first excitation electrode. For example, the two notched portions may be disposed side by side at a distance in the Z′-axis direction. At this time, the sum of the hole portion length Wh12 and the hole portion length Wh22 is equal to or larger than the second electrode length Le2 (Le2 ≤Wh12+Wh22). The planar shape of the two notched portions may be, for example, a rectangular shape, a square shape, another polygonal shape, a circular shape, an elliptical shape, or a combination thereof. The planar shapes of the two notched portions may be different from each other. In addition, the areas of the two notched portions may be different from each other. For example, the relationship of Wh11<Wh21 or Wh11>Wh21 may be established, and the relationship of Wh12<Wh22 or Wh12>Wh22 may be established.

An additional hole portion may be further formed in addition to the two notched portions in the first excitation electrode. The additional hole portion is formed, for example, between the two notched portions and separated from the two notched portions. The planar shape of the additional hole portion is not particularly limited, and may be, for example, a rectangular shape, a square shape, another polygonal shape, a circular shape, an elliptical shape, or a combination thereof. In addition, the area of the additional hole portion is not particularly limited, and may be smaller than or larger than, or the same as the areas of the two notched portions.

### Seventh Embodiment

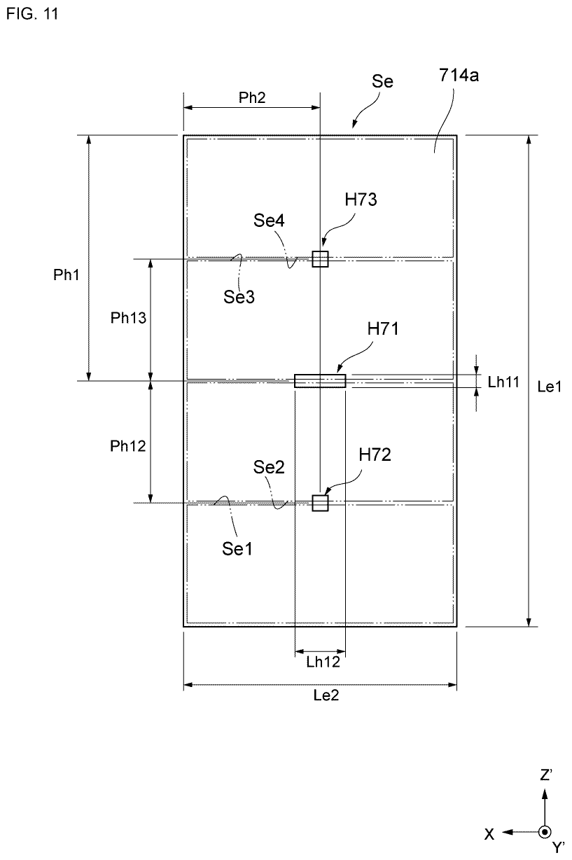

Hole portions H71, H72, and H73 are formed in the first excitation electrode 714a illustrated in FIG. 11. Among the hole portions H71, H72, and H73, the hole portion H71 is the same as the hole portion H1 of the first embodiment. The hole portion H72 corresponds to an example of a “second hole portion”. The hole portion H73 corresponds to an example of a “third hole portion”.

The hole portion H72 is formed in the central portion in the Z′-axis direction of the portion, which is on the negative direction side of the Z′-axis direction with respect to the hole portion H71, of the first excitation electrode 714a. In addition, the hole portion H72 is formed in the central portion of the first excitation electrode 714a in the X-axis direction. The hole portion H72 is separated from the hole portion H71, the short side of the first excitation electrode 714a on the negative direction side of the Z′-axis direction, the long side of the first excitation electrode 714a on the negative direction side of the X-axis direction, and the long side of the first excitation electrode 714a on the positive direction side in the X-axis direction. The hole portion H72 is provided between the hole portion H71 and the short side of the first excitation electrode 714a on the negative direction side of the Z′-axis direction.

The hole portion H73 is formed in the central portion in the Z′-axis direction of the portion, which is on the positive direction side of the Z′-axis direction with respect to the hole portion H71, of the first excitation electrode 714a. In addition, the hole portion H73 is formed in the central portion of the first excitation electrode 714a in the X-axis direction. The hole portion H73 is separated from the hole portion H71, the short side of the first excitation electrode 714a on the positive direction side of the Z′-axis direction, the long side of the first excitation electrode 714a on the negative direction side of the X-axis direction, and the long side of the first excitation electrode 714a on the positive direction side in the X-axis direction. The hole portion H73 is provided between the hole portion H71 and the short side of the first excitation electrode 714a on the positive direction side of the Z′-axis direction.

The planar shape of the hole portions H72 and H73 is a square shape having a side that extends in the Z′-axis direction and a side that extends in the X-axis direction. Each side of the hole portions H72 and 73 is substantially the same size as the short side of the hole portion H71. Therefore, the area of each of the hole portions H72 and H73 are smaller than the area of the hole portion H71.

When viewed in plan view, the geometric centers of the hole portions H71, H72, and H73 are positioned on the center line that extends in the Z′-axis direction through the geometric center of the first excitation electrode 714a, and are disposed side by side in the Z′-axis direction. In other words, all the distances of the geometric centers of the hole portions H71, H72, and H73 along the X-axis direction from the long side of the first excitation electrode 714a are the second hole portion distance Ph2. The distance between the geometric center of the hole portion H71 and the geometric center of the hole portion H72 (hereinafter, referred to as a “hole portion gap Ph12”) in the Z′-axis direction is substantially one-fourth of the first electrode length Le1, and is substantially one-half of the first hole portion distance Ph1 (Ph12=(¼)×Le1 and Ph12=(½)×Ph1). The same also applies to the distance between the geometric center of the hole portion H71 and the geometric center of the hole portion H73 (hereinafter, referred to as a “hole portion gap Ph13”) in the Z′-axis direction (Ph13=(¼)×Le1 and Ph13=(½)×Ph1). Therefore, the hole portion gap Ph12 and the hole portion gap Ph13 are substantially equal (Ph12=Ph13).

The electrode area of the first excitation electrode 714a is defined as Se, the area of the portion in the first excitation electrode 714a on the negative direction side of the Z′-axis direction of the hole portion H72 is defined as Se1, the area of the portion in the first excitation electrode 714a on the positive direction side of the Z′-axis direction of the hole portion H72 and on the negative direction side of the Z′-axis direction of the hole portion H71 is defined as Se2, the area of the portion in the first excitation electrode 714a on the positive direction side of the Z′-axis direction of the hole portion H71 and on the negative direction side of the Z′-axis direction of the hole portion H73 is defined as Se3, and the area of the portion in the first excitation electrode 714a on the positive direction side of the Z′-axis direction of the hole portion H73 is defined as Se4. For example, the areas Se1 to Se4 are substantially equal to each other (Se1≈Se2≈Se3≈Se4). In other words, the hole portion H71 is formed at a position that bisects the area of the first excitation electrode 714a in the Z′-axis direction. In addition, the hole portion H72 is formed at a position that bisects the area of the portion, which is on the negative direction side in the Z′-axis direction of the hole portion H71, of the first excitation electrode 714a in the Z′-axis direction. In addition, the hole portion H73 is formed at a position that bisects the area of the portion, which is on the positive direction side in the Z′-axis direction of the hole portion H71, of the first excitation electrode 714a in the Z′-axis direction. Summarizing, the hole portions H71, H72, and H73 are formed at positions that divide the electrode area Se of the first excitation electrode 714a into four equal parts in the Z′-axis direction.

When the second hole portion is formed in the central portion in the Z′-axis direction of the portion, which is on the negative direction side of the Z′-axis direction with respect to the first hole portion, of the first excitation electrode, the position, the planar shape, and the size are not limited to the above. Similarly, when the third hole portion is formed in the central portion in the Z′-axis direction of the portion, which is on the positive direction side of the Z′-axis direction with respect to the first hole portion, of the first excitation electrode, the position, the planar shape, and the size are not limited to the above. For example, the geometric centers of the second hole portion and the third hole portion may be separated from the center line that extends in the Z′-axis direction of the first excitation electrode. In addition, the geometric centers of the second hole portion and the third hole portion need not be disposed side by side with the geometric center of the first hole portion in the Z′-axis direction. The second hole portion may be formed at a position at which the relationship of Ph12>(½)×Ph1 or Ph12<(½)×Ph1 is established, and the third hole portion may be formed at a position at which the relationship of Ph13>(½)×Ph1 or Ph13<(½)×Ph1 is established. In addition, the second hole portion may be formed at a position at which the relationship of Se1>Se2 or Se1<Se2 is established, and the third hole portion may be formed at a position at which the relationship of Se3>Se4 or Se3<Se4 is established.

The planar shapes of the second hole portion and the third hole portion may be a rectangular shape having a long side that extends in the X-axis direction, a rectangular shape having a long side that extends in the Z′-axis direction, another polygonal shape, a circular shape, an elliptical shape, or a combination thereof. In addition, the second hole portion and the third hole portion may include a plurality of small holes, and may include a notched cavity that is open on the positive direction side or the negative direction side of the X-axis direction of the first excitation electrode. The area of each of the second hole portion and the third hole portion may be substantially equal to the area of the first hole portion or may be larger than the area of the first hole portion. The area of the second hole portion and the area of the third hole portion may be different from each other.

### Eighth Embodiment

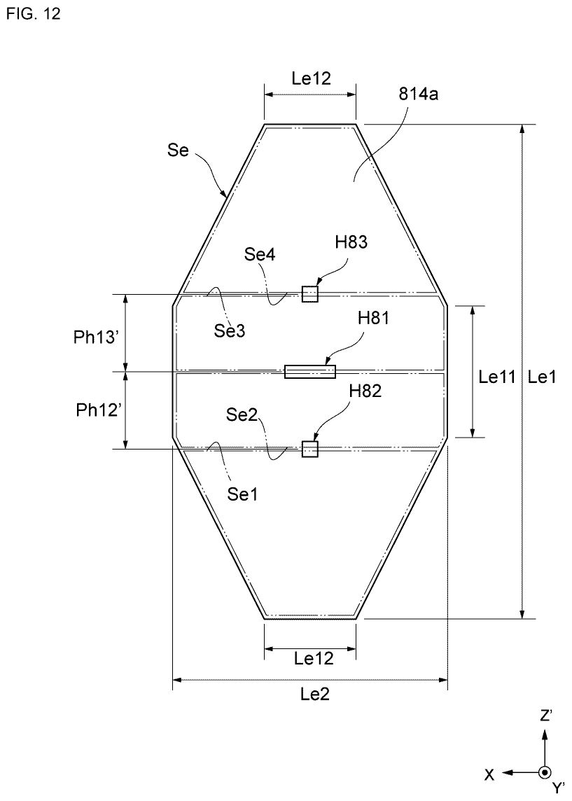

The first excitation electrode 814a illustrated in FIG. 12 has an octagonal shape, and hole portions H81, H82, and H83 are formed in the first excitation electrode 814a. The shape and the size of the hole portions H81, H82, and H83 are the same as those of the hole portions H71 to H73 according to the seventh embodiment.

The planar shape of the first excitation electrode 814a is an octagonal shape obtained by shaving a square shape into a triangular shape from the first excitation electrode 714a according to the seventh embodiment. That is, the first excitation electrode 814a has a side that extends in the Z′-axis direction, a side that extends in the X-axis direction, and a side that connects the sides. The dimension of the side that extends in the X-axis direction of the first excitation electrode 814a is defined as a short side length Le12, and the dimension of the side that extends in the Z′-axis direction is defined as a long side length Le11. The short side length Le12 is smaller than the second electrode length Le2, and the long side length Le11 is smaller than the first electrode length Le1. For example, the short side length Le12 is smaller than the long side length Le11.

The hole portion H81 is formed such that the geometric center thereof coincides with the geometric center of the first excitation electrode 814a, and the hole portions H82 and H83 are formed at positions such that Se1=Se2=Se3=Se4=(¼)×Se. The geometric centers of the hole portions H81, H82, and H83 are disposed side by side in the Z′-axis direction. The distance between the geometric center of the hole portion H81 and the geometric center of the hole portion H82 (hereinafter, referred to as a “hole portion gap Ph12′”) in the Z′-axis direction is smaller than the hole portion gap Ph12 according to the seventh embodiment (Ph12′<Ph12). The distance between the geometric center of the hole portion H81 and the geometric center of the hole portion H83 (hereinafter, referred to as a “hole portion gap Ph13”) in the Z′-axis direction is smaller than the hole portion gap Ph13 according to the seventh embodiment (Ph13′<Ph13). The hole portion gap Ph12′ and the hole portion gap Ph13′ are substantially equal (Ph12′=Ph13′). For example, the sum of the hole portion gap Ph12′ and the hole portion gap Ph13′ is larger than the long side length Le11 (Le11<Ph12′+Ph13′).

When the short side length on the positive direction side of the Z′-axis direction and the short side length on the negative direction side of the Z′-axis direction of the first excitation electrode are different from each other, the hole portion gap Ph12′ and the hole portion gap Ph13′ are different from each other (Ph12′≠Ph13′). In addition, the magnitude relationship between the hole portion gap Ph12′, the hole portion gap Ph13′, and the long side length Le11 is not limited to Le11<Ph12′+Ph13′. The sum of the hole portion gap Ph12′ and the hole portion gap Ph13′ may be substantially equal to the long side length Le11 (Le11=Ph12′+Ph13′) or may be smaller than the long side length Le11 (Ph12′+Ph13′<Le11).

### Ninth Embodiment

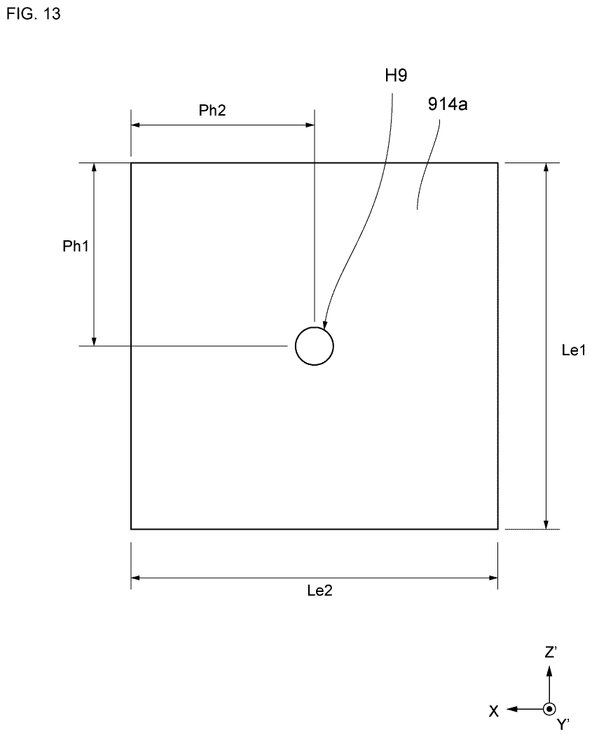

The planar shape of the first excitation electrode 914a illustrated in FIG. 13 is a square shape, and the planar shape of a hole portion H9 formed in the first excitation electrode 914a is a circular shape.

The first electrode length Le1 and the second electrode length Le2 are substantially equal (Le1=Le2). A relationship of 45≤Le1/Tq≤120 is established between the crystal thickness Tq and the first electrode length Le1. In addition, the relationship of 45≤Le2/Tq≤120 is established between the crystal thickness Tq and the second electrode length Le2. The hole portion H9 is positioned in the central portion of the first excitation electrode 914a in the Z′-axis direction and in the central portion of the first excitation electrode 914a in the X-axis direction. That is, the first hole portion distance Ph1 is substantially equal to the second hole portion distance Ph2 (Ph1=Ph2).

Although the planar shape of the first excitation electrode is a square shape as in the present embodiment, similarly to the case where the planar shape of the first excitation electrode is a rectangular shape, the planar shape of the first hole portion is not particularly limited. The planar shape of the first hole portion formed in the first excitation electrode of a square shape may be a rectangular shape having a long side that extends in the X-axis direction, a rectangular shape having a long side that extends in the Z′-axis direction, a square shape, another polygonal shape, a circular shape, an elliptical shape, or a combination thereof. The first hole portion formed in the first excitation electrode of a square shape may include a plurality of small holes. In addition, the first hole portion formed in the first excitation electrode of a square shape may include a notched cavity that is open on the positive direction side or the negative direction side of the X-axis direction of the first excitation electrode, or may include a notched cavity that is open on the positive direction side or the negative direction side in the Z′-axis direction of the first excitation electrode.

In the first excitation electrode of a square shape, the second hole portion may be formed in the central portion in the Z′-axis direction of the portion that is on the negative direction side of the Z′-axis direction with respect to the first hole portion, and the third hole portion may be formed in the central portion in the Z′-axis direction of the portion that is on the positive direction side of the Z′-axis direction with respect to the first hole portion. In addition, in the first excitation electrode of a square shape, a fourth hole portion may be formed in the central portion in the X-axis direction of the portion that is on the negative direction side of the X-axis direction with respect to the first hole portion, and a fifth hole portion may be formed in the central portion in the X-axis direction of the portion that is on the positive direction side of the X-axis direction with respect to the first hole portion. For example, the position and the planar shape of the fourth hole portion and the fifth hole portion are the same as the position and the planar shape of the second hole portion and the third hole portion rotated by 90 degrees about the Y′-axis. In addition, for example, the areas of the fourth hole portion and the fifth hole portion are the same as the areas of the second hole portion and the third hole portion. All of the second hole portion, the third hole portion, the fourth hole portion, and the fifth hole portion may be formed in the first excitation electrode of a square shape.

### EXAMPLE

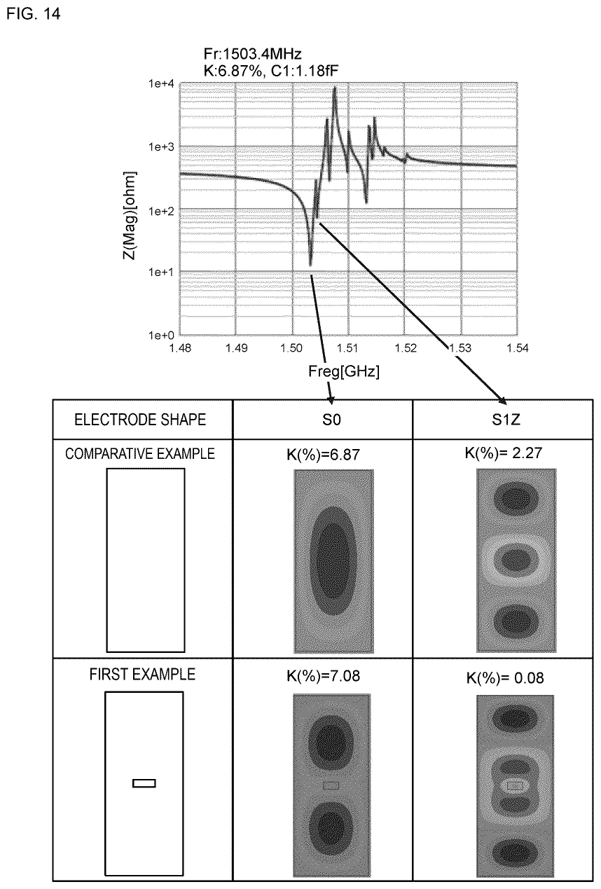

Next, a first example will be described with reference to FIG. 14. FIG. 14 is a diagram illustrating a simulation result in the first example. The first example is a vibration simulation of the quartz crystal resonator including the first excitation electrode according to the first embodiment, and a comparative example is a crystal vibration simulation of the quartz crystal resonator that is the same as that of the first example except that the first hole portion is not formed.

### First Example

### Quartz Crystal Element

Cut-angles: AT cut
Planar shape: a square shape
Upper surface dimension: 140 μm×140 μm
Thickness Tq: 1 μm
Main mode S0: 1.45 GHz

### First Excitation Electrode

Material: Aluminum (Al) or Aluminum-Copper Alloy (AlCu)
First electrode length Le1: 120 μm (Le1/Tq=120)
Second electrode length Le2: 50 μm (Le2/Tq=50)
Electrode thickness Te: 0.05 μm

### First Hole Portion

First hole portion length Lh11: 5 μm
Second hole portion length Lh12: 15 μm

The electromechanical coupling coefficient K of the main mode S0 is 6.87(%) in the comparative example, but is increased to 7.08 in the first example. In the inharmonic modes in which a plurality of vibration antinodes are disposed side by side in the Z′-axis direction, the electromechanical coupling coefficient K of an inharmonic mode S1Z whose frequency is closest to the main mode S0 is 2.27(%) in the comparative example, but is decreased to 0.08 in the first example. When the distribution of the vibration of the inharmonic mode S1Z is looked at, in the first example, the vibration range of the central portion is expanded, and thus the vibrations in opposite phases cancel each other, so that K of the inharmonic mode S1Z seems to be decreased. Since the K of the inharmonic mode S1Z is decreased, it seems that the influence of the inharmonic mode S1Z on the main mode S0 is reduced and the K of the main mode S0 is increased. As described above, in the first example based on the first embodiment, the electromechanical coupling coefficient K of the main mode S0 and the inharmonic mode S1Z is improved as compared with the comparative example.

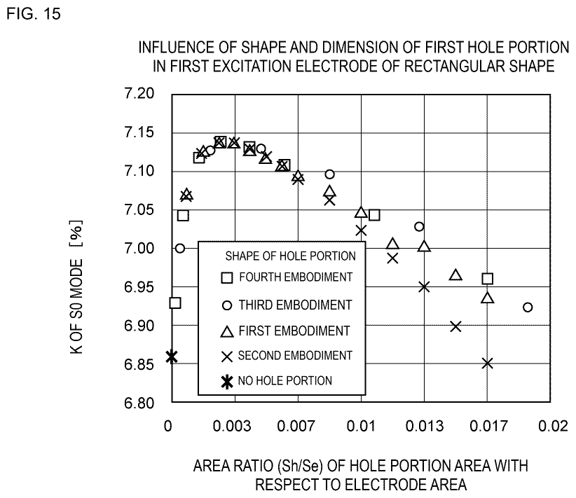

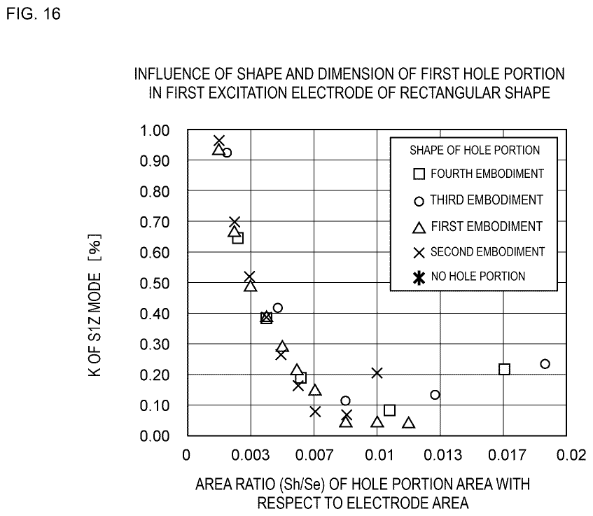

Next, the electromechanical coupling coefficient K when the shape and the dimension of the first hole portion of the first example are changed will be described with reference to FIGS. 15 and 16. FIG. 15 is a graph illustrating the influence of the shape and the dimension of the first hole portion in the first excitation electrode of a rectangular shape. FIG. 16 is a graph illustrating the influence of the shape and the dimension of the first hole portion in the first excitation electrode of a rectangular shape. The horizontal axes in FIGS. 15 and 16 indicate the ratio Sh/Se of a hole portion area Sh of the first hole portion with respect to the electrode area Se of the first excitation electrode, the vertical axis in FIG. 15 indicates the electromechanical coupling coefficient K (%) of the main mode S0, and the vertical axis in FIG. 16 indicates the electromechanical coupling coefficient K (%) of the inharmonic mode S1Z.

FIGS. 15 and 16 plots simulation results based on an example in which the shape of the first hole portion from the first example is changed to a rectangular shape based on the second embodiment, an example in which the shape of the first hole portion from the first example is changed to a circular shape based on the third embodiment, and an example in which the shape of the first hole portion from the first example is changed to a square shape based on the fourth embodiment.

As illustrated in FIGS. 15 and 16, the contribution of the planar shape of the first hole portion to the electromechanical coupling coefficient K of the main mode S0 and the inharmonic mode S1Z is small. In addition, the electromechanical coupling coefficient K of the main mode S0 and the inharmonic mode S1Z is greatly affected by an area ratio Har=Sh/Se of the hole portion area Sh of the first hole portion with respect to the electrode area Se of the first excitation electrode. Specifically, the electromechanical coupling coefficient K of the main mode S0 increases as Har=Sh/Se increases when Har=Sh/Se is from 0 to approximately 0.003, regardless of the planar shape of the first hole portion, and decreases as Har=Sh/Se increases when Har=Sh/Se is larger than approximately 0.003. The electromechanical coupling coefficient K of the inharmonic mode S1Z decreases as Har=Sh/Se increases when Har=Sh/Se is from 0 to approximately 0.008, regardless of the planar shape of the first hole portion, and increases as Har=Sh/Se increases when Har=Sh/Se is larger than approximately 0.008.

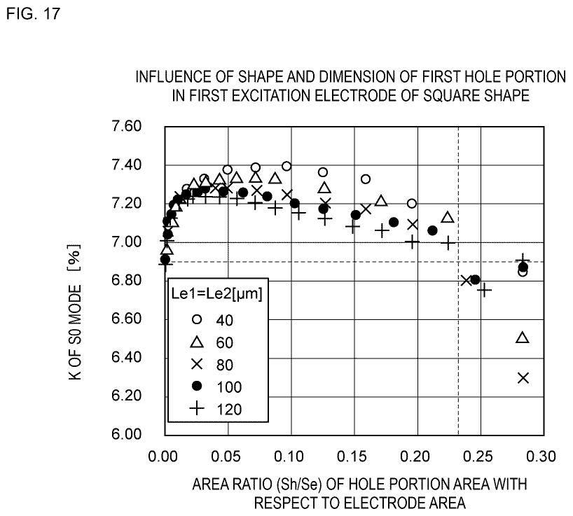

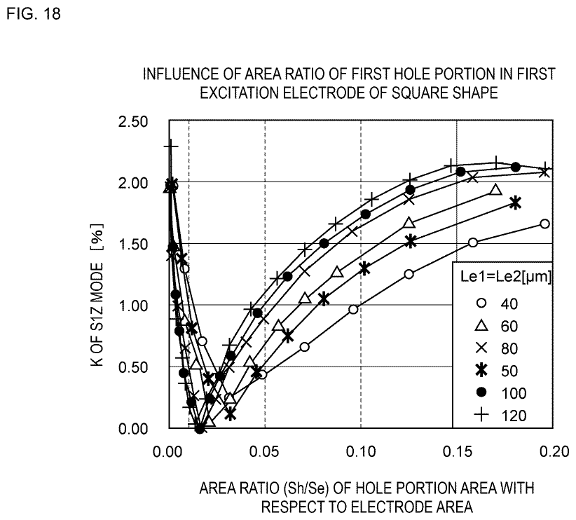

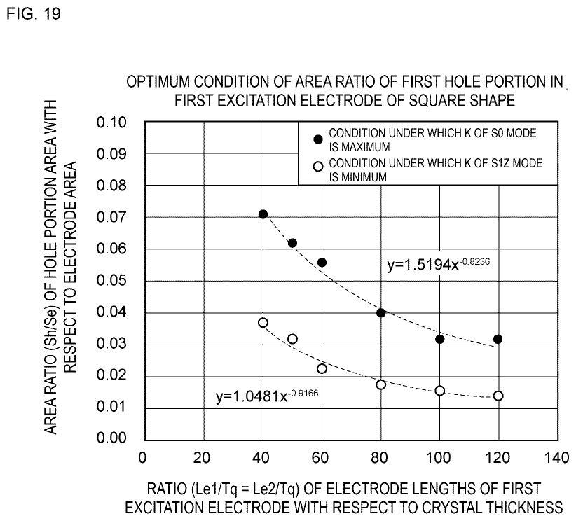

Next, with reference to FIGS. 17 to 19, in an example based on the ninth embodiment, a simulation result related to the electromechanical coupling coefficient when the area ratio Har=Sh/Se of the first hole portion with respect to the electrode area Se of the first excitation electrode is changed, will be described. The example used for the simulation is the same as the first example except for the shape and dimension of the first excitation electrode and the first hole portion. FIG. 17 is a graph illustrating an influence of an area ratio of the first hole portion in the first excitation electrode of a square shape. FIG. 18 is a graph illustrating the influence of the area ratio of the first hole portion in the first excitation electrode of a square shape. FIG. 19 is a graph illustrating an optimum condition of an area ratio of the first hole portion in the first excitation electrode of a square shape. The horizontal axes in FIGS. 17 and 18 indicate the area ratio Har=Sh/Se of the hole portion area Sh of the first hole portion with respect to the electrode area Se of the first excitation electrode, the vertical axis in FIG. 17 indicates the electromechanical coupling coefficient K (%) of the main mode S0, and the vertical axis in FIG. 18 indicates the electromechanical coupling coefficient K (%) of the inharmonic mode S1Z. The horizontal axis in FIG. 19 indicates the ratio Le1/Tq=Le2/Tq of the electrode lengths Le1 and Le2 (Le1=Le2) with respect to the crystal thickness Tq, and the vertical axis in FIG. 19 indicates the area ratio Har=Sh/Se of the hole portion area Sh of the first hole portion with respect to the electrode area Se of the first excitation electrode.

FIG. 17 plots a simulation result of the electromechanical coupling coefficient K of the main mode S0 when the area ratio Har=Sh/Se is changed in a case where the electrode lengths Le1 and Le2 (Le1=Le2) are 40 μm, 60 μm, 80 μm, 100 μm, and 120 μm. FIG. 18 plots a simulation result of the electromechanical coupling coefficient K of the inharmonic mode S1Z when the area ratio Har=Sh/Se is changed in a case where the electrode lengths Le1 and Le2 (Le1=Le2) are 40 μm, 60 μm, 80 μm, 50 μm, 100 μm, and 120 μm. The change in the area ratio Har=Sh/Se is realized by changing a radius R of the first hole portion. As described with reference to FIGS. 15 and 16, since the contribution of the planar shape of the first hole portion with respect to the electromechanical coupling coefficient K is small, the planar shape of the first hole portion is fixed to change the area ratio Har=Sh/Se, so that the tendency of change of the electromechanical coupling coefficient K can be known.

As illustrated in FIG. 17, the electromechanical coupling coefficient K of the main mode S0 indicates an upward convex graph within a range of 0<Har<0.30. The area ratio Har at which the electromechanical coupling coefficient K of the main mode S0 is maximum differs depending on the electrode lengths Le1 and Le2. The area ratio Har at which the electromechanical coupling coefficient K of the main mode S0 is maximum increases as the electrode lengths Le1 and Le2 decrease. In addition, the smaller the electrode lengths Le1 and Le2, the larger the maximum value of the electromechanical coupling coefficient K of the main mode S0. The electromechanical coupling coefficient K of the main mode S0 is increased as compared with the configuration without a hole portion (Har=0) in a range of 0<Har≤0.23. As illustrated in FIG. 18, the electromechanical coupling coefficient K of the inharmonic mode S1Z indicates a downward convex graph within a range of 0<Har<0.20. The area ratio Har at which the electromechanical coupling coefficient K of the inharmonic mode S1Z is minimum differs depending on the electrode lengths Le1 and Le2. The area ratio Har at which the electromechanical coupling coefficient K of the inharmonic mode S1Z is minimum decreases as the electrode lengths Le1 and Le2 increase. In addition, the minimum value of the electromechanical coupling coefficient K of the inharmonic mode S1Z decreases as the electrode lengths Le1 and Le2 increase. The electromechanical coupling coefficient K of the inharmonic mode S1Z is decreased as compared with the configuration without a hole portion (Har=0) in a range of 0<Har≤0.1. The electromechanical coupling coefficient K of the inharmonic mode S1Z is further decreased in a range of 0.01≤Har≤0.05.

As illustrated by the approximation expression in FIG. 19, the electromechanical coupling coefficient K of the main mode S0 is maximum when, within a range of 0<Har≤0.23, a relationship of Har=1.52×(Le2/Tq)^{-0.82}±0.01 is established.

As illustrated in the approximation expression in FIG. 19, the electromechanical coupling coefficient K of the inharmonic mode S1Z is minimum when, within a range of 0.01≤Har≤0.05, a relationship of Har=1.05×(Le2/Tq)^{-0.92}±0.01 is established.

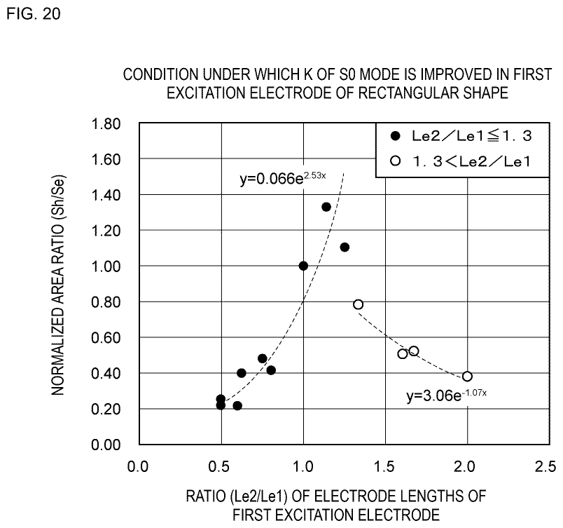

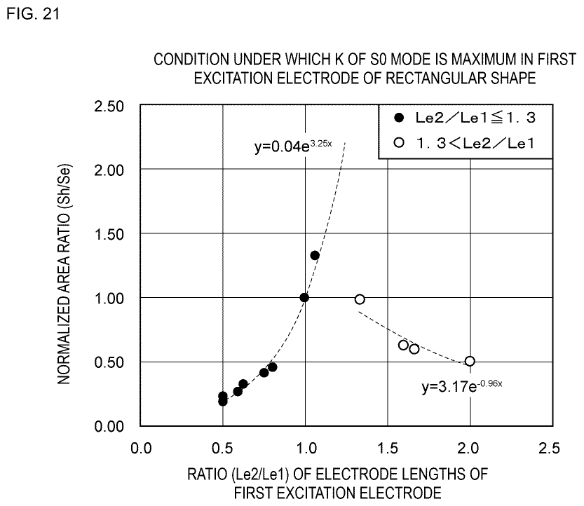

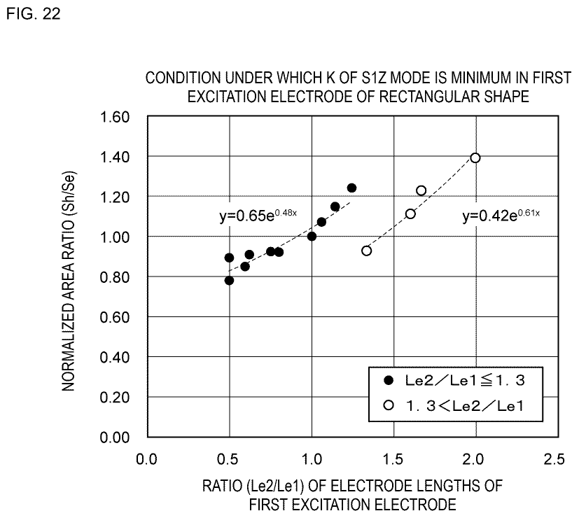

Next, with reference to FIGS. 20 to 22, in the example based on the third embodiment, a simulation result when the area ratio Har=Sh/Se of the hole portion area of the first hole portion with respect to the electrode area Se of the first excitation electrode is changed, will be described. The example used for the simulation is the same as the first example except for the shape and the dimension of the first hole portion. FIG. 20 is a graph illustrating a condition under which K of the S0 mode is increased in the first excitation electrode of a rectangular shape. FIG. 21 is a graph illustrating a condition under which K of the S0 mode is maximum in the first excitation electrode of a rectangular shape. FIG. 22 is a graph illustrating a condition under which K of the S1Z mode is minimum in the first excitation electrode of a rectangular shape. The horizontal axes of FIGS. 20 to 22 are the ratio Le2/Le1 of the second electrode length Le2 with respect to the first electrode length Le1 of the first excitation electrode. The vertical axes in FIGS. 20 to 22 are values obtained by normalizing the area ratio Har=Sh/Se of the hole portion area Sh of the first hole portion with respect to the electrode area Se of the first excitation electrode by Har of Le2/Le1=1.

As illustrated in FIG. 20, the tendency of a condition under which the electromechanical coupling coefficient K of the main mode S0 is increased as compared with the comparative example having no first hole portion differs at the boundary of Le2/Le1=1.3. As illustrated in FIG. 21, similarly, the tendency of the condition under which the electromechanical coupling coefficient K of the main mode S0 is maximum also differs at the boundary of Le2/Le1=1.3. As illustrated in FIG. 22, similarly, the tendency of the condition under which the electromechanical coupling coefficient K of the inharmonic mode S1Z is minimum also differs at the boundary of Le2/Le1=1.3.

As illustrated in the approximation expression in FIG. 20, when 0.5≤Le2/Le1≤1.3 and Le2/Le1≠1.0, the condition under which the electromechanical coupling coefficient K of the main mode S0 is increased as compared with the comparative example having no first hole portion is that 0<Har≤0.23×0.066×exp(2.53×Le2/Le1)=0.015×exp(2.53×Le2/Le1) is established. The condition range of Har, in which the electromechanical coupling coefficient K of the main mode S0 in the first excitation electrode of a rectangular shape is increased, is calculated by the product of a conditional expression (1) related to Har(SQ) and a conditional expression (2) related to Har(N) (Har=Har(SQ)×Har(N)). The conditional expression (1) related to Har(SQ) is a condition under which the electromechanical coupling coefficient K of the main mode S0 is increased, in the first excitation electrode of a square shape (Le2/Le1=1.0) which is a normalization condition. The conditional expression (2) related to Har(N) is a condition under which the electromechanical coupling coefficient K of the main mode S0 which is normalized by Le2/Le1=1.0 is increased, in the first excitation electrode of a rectangular shape which satisfies the relationship of 0.5≤Le2/Le1≤1.3. The conditional expression (1) related to Har(SQ) is represented by the following inequality described with reference to FIG. 17.

$$0 < Har ( SQ ) \leq 0.23 \qquad ( 1 )$$

The conditional expression (2) related to Har(N) is represented by the following approximation expression illustrated in FIG. 20.

$$Har ( N ) = 0.066 \times exp ( 2.53 \times Le 2 / Le 1 ) \qquad ( 2 )$$

As illustrated in the approximation expression in FIG. 21, when 0.5≤Le2/Le1≤1.3 and Le2/Le1≠1.0, the condition under which the electromechanical coupling coefficient K of the main mode S0 is maximum is that, within the above range, Har=0.04×exp(3.25×Le2/Le1)×1.52×(Le2/Tq)^{-0.82}±0.01=0.061×exp(3.25×Le2/Le1)×(Le2/Tq)^{-0.82}±0.01 is further established. The conditional expression in which the electromechanical coupling coefficient K of the main mode S0 in the first excitation electrode of a rectangular shape is maximum is calculated by the product of the conditional expression (3) related to Har(SQ) and the conditional expression (4) related to Har(N). The conditional expression (3) related to Har(SQ) is a condition under which the electromechanical coupling coefficient K of the main mode S0 is maximum, in the first excitation electrode of a square shape (Le2/Le1=1.0) which is a normalization condition. The conditional expression (4) related to Har(N) is a condition under which the electromechanical coupling coefficient K of the main mode S0 which is normalized by Le2/Le1=1.0 is maximum, in the first excitation electrode of a rectangular shape which satisfies the relationship of 0.5≤Le2/Le1≤1.3. The conditional expression (3) related to Har(SQ) is represented by the following approximation expression described with reference to FIG. 19.

$$Har ( SQ ) = 1.52 \times {( Le 2 / Tq )}^{- 0.82} \pm 0.01 \qquad ( 3 )$$

The conditional expression (4) related to Har(N) is represented by the approximation expression illustrated in FIG. 21.

$$Har ( N ) = 0.04 \times exp ( 3.25 \times Le 2 / Le 1 ) \qquad ( 4 )$$

As illustrated in the approximation expression in FIG. 20, when 1.3<Le2/Le1≤2.0, the condition under which the electromechanical coupling coefficient K of the main mode S0 is increased compared to the comparative example having no first hole portion is that 0<Har≤0.23×3.06×exp(−1.07×Le2/Le1)=0.704×exp(−1.07×Le2/Le1) is established. The condition range described above is also calculated by the product of the conditional expression (1) related to Har(SQ) and the conditional expression (5) related to Har(N), similarly to the condition range when 0.5≤Le2/Le1≤1.3 and Le2/Le1≠1.0. The conditional expression (5) related to Har(N) is a condition under which the electromechanical coupling coefficient K of the main mode S0 which is normalized by Le2/Le1=1.0 is increased, in the first excitation electrode of a rectangular shape which satisfies the relationship of 1.3≤Le2/Le1≤2.0. The conditional expression (5) related to Har(N) is represented by the following approximation expression illustrated in FIG. 20.

$$Har ( N ) = 3.06 \times exp ( - 1.07 \times Le 2 / Le 1 ) \qquad ( 5 )$$

As illustrated in the approximation expression in FIG. 21, when 1.3<Le2/Le1≤2.0, the condition under which the electromechanical coupling coefficient K of the main mode S0 is maximum is that, further within the above range, Har=3.17×exp(−0.96×Le2/Le1)×1.52×(Le2/Tq)^{-0.82}±0.01=4.82×exp(−0.96×Le2/Le1)×(Le2/Tq)^{-0.82}±0.01 is further established. The conditional expression described above is also calculated by the product of the conditional expression (3) related to Har(SQ) and the conditional expression (6) related to Har(N), similarly to the conditional expression when 0.5≤Le2/Le1≤1.3 and Le2/Le1≠1.0. The conditional expression (6) related to Har(N) is a condition under which the electromechanical coupling coefficient K of the main mode S0 which is normalized by Le2/Le1=1.0 is maximum, in the first excitation electrode of a rectangular shape which satisfies the relationship of 1.3≤Le2/Le1≤2.0. The conditional expression (6) related to Har(N) is represented by the following approximation expression illustrated in FIG. 21.

$$Har ( N ) = 3.17 \times exp ( - 0.96 \times Le 2 / Le 1 ) \qquad ( 6 )$$

As illustrated in FIG. 16, when Le2/Le1≠1.0, the electromechanical coupling coefficient K of the inharmonic mode S1Z is decreased as compared with the configuration without the first hole portion (Har=0) in a range of 0<Har≤0.02.

As illustrated in the approximation expression in FIG. 22, when 0.5≤Le2/Le1≤1.3 and Le2/Le1≠1.0, the condition under which the electromechanical coupling coefficient K of the inharmonic mode S1Z is minimum is that Har=0.65×exp(0.48×Le2/Le1)×1.05×(Le2/Tq)^{-0.92}±0.01=0.68×exp(0.48×Le2/Le1)×(Le2/Tq)^{-0.92}±0.01 is established. The conditional expression in which the electromechanical coupling coefficient K of the inharmonic mode S1Z in the first excitation electrode of a rectangular shape is minimum is calculated by the product of the conditional expression (7) related to Har(SQ) and the conditional expression (8) related to Har(N). The conditional expression (7) related to Har(SQ) is a condition under which the electromechanical coupling coefficient K of the inharmonic mode S1Z is minimum, in the first excitation electrode of a square shape (Le2/Le1=1.0) which is a normalization condition. The conditional expression (8) related to Har(N) is a condition under which the electromechanical coupling coefficient K of the inharmonic mode S1Z which is normalized by Le2/Le1=1.0 is minimum, in the first excitation electrode of a rectangular shape which satisfies the relationship of 0.5≤Le2/Le1≤1.3. The conditional expression (7) related to Har(SQ) is represented by the following approximation expression described with reference to FIG. 19.

$$Har ( SQ ) = 1.05 \times {( Le 2 / Tq )}^{- 0.92} \pm 0.01 \qquad ( 7 )$$

The conditional expression (8) related to Har(N) is represented by the following approximation expression illustrated in FIG. 22.

$$Har ( N ) = 0.65 \times exp ( 0.48 \times Le 2 / Le 1 ) \qquad ( 8 )$$

As illustrated in the approximation expression in FIG. 22, when 1.3<Le2/Le1≤2.0, the condition under which the electromechanical coupling coefficient K of the inharmonic mode S1Z is minimum is that Har=0.42×exp (0.61×Le2/Le1)×1.05×(Le2/Tq)^{-0.92}±0.01=0.44×exp(0.61×Le2/Le1)×(Le2/Tq)^{-0.92}±0.01 is established. The conditional expression described above is also calculated by the product of the conditional expression (7) related to Har(SQ) and the conditional expression (9) related to Har(N), similarly to the conditional expression when 0.5≤Le2/Le1≤1.3 and Le2/Le1≠1.0. The conditional expression (9) related to Har(N) is a condition under which the electromechanical coupling coefficient K of the inharmonic mode S1Z which is normalized by Le2/Le1=1.0 is minimum, in the first excitation electrode of a rectangular shape which satisfies the relationship of 1.3≤Le2/Le1≤2.0. The conditional expression (9) related to Har(N) is represented by the following approximation expression illustrated in FIG. 22.

$$Har = 0.42 \times exp ( 0.61 \times Le 2 / Le 1 ) \qquad ( 9 )$$

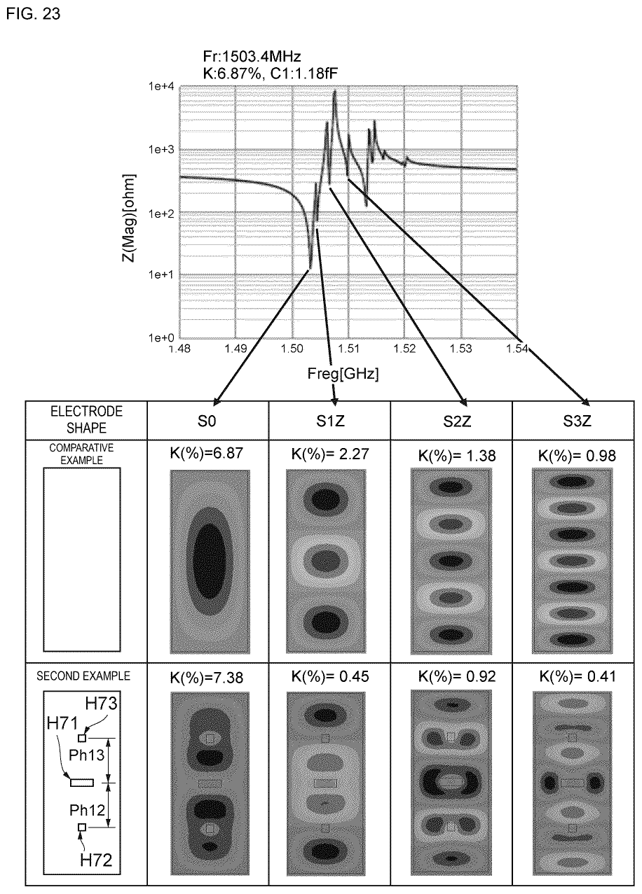

Next, a second example will be described with reference to FIG. 23. FIG. 23 is a diagram illustrating a simulation result in the second example. The second example is a vibration simulation of the quartz crystal resonator including the first excitation electrode according to the seventh embodiment, and a comparative example is a vibration simulation of the quartz crystal resonator that is the same as that of the second example except that the first hole portion, the second hole portion, and the third hole portion are not formed. The second example has the same condition as that of the first example except for the second hole portion and the third hole portion.

### Second Example

### Quartz Crystal Element

Cut-angles: AT cut
Planar shape: a square shape
Upper surface dimension: 140 μm×140 μm
Thickness Tq: 1 μm
Main mode S0: 1.45 GHz

### First Excitation Electrode

Material: Aluminum (Al) or Aluminum-Copper Alloy (AlCu)
First electrode length Le1: 120 μm (Le1/Tq=120)
Second electrode length Le2: 50 μm (Le2/Tq=50)
Electrode thickness Te: 0.05 μm

### First Hole Portion (the Hole Portion H71)

First hole portion length Lh11: 5 μm
Second hole portion length Lh12: 15 μm

### Second Hole Portion (the Hole Portion H72) and Third Hole Portion (the Hole Portion H73)

Planar shape: a square shape
Planar dimension: 5 μm×5 μm
Hole portion gap Ph12: 30 μm
Hole portion gap Ph13: 30 μm

The electromechanical coupling coefficient K of the main mode S0 is 6.87(%) in the comparative example, but is increased to 7.38 in the second example. In the inharmonic modes in which a plurality of vibration antinodes are disposed side by side in the Z′-axis direction, the electromechanical coupling coefficient K of the inharmonic mode S1Z whose frequency is closest to the main mode S0 is 2.27(%) in the comparative example, but is decreased to 0.45 in the second example. In the inharmonic modes in which a plurality of vibration antinodes are disposed side by side in the Z′-axis direction, the electromechanical coupling coefficient K of an inharmonic mode S2Z whose frequency is closest to the main mode S0 next to the inharmonic mode S1Z is 1.38(%) in the comparative example, but is decreased to 0.92 in the second example. In the inharmonic modes in which a plurality of vibration antinodes are disposed side by side in the Z′-axis direction, the electromechanical coupling coefficient K of an inharmonic mode S3Z whose frequency is closest to the main mode S0 next to the inharmonic mode S2Z is 0.98(%) in the comparative example, but is decreased to 0.41 in the second example. As described above, in the second example based on the seventh embodiment, the electromechanical coupling coefficient K of the main mode S0, the inharmonic mode S1Z, the inharmonic mode S2Z, and the inharmonic mode S1Z is improved as compared with the comparative example.

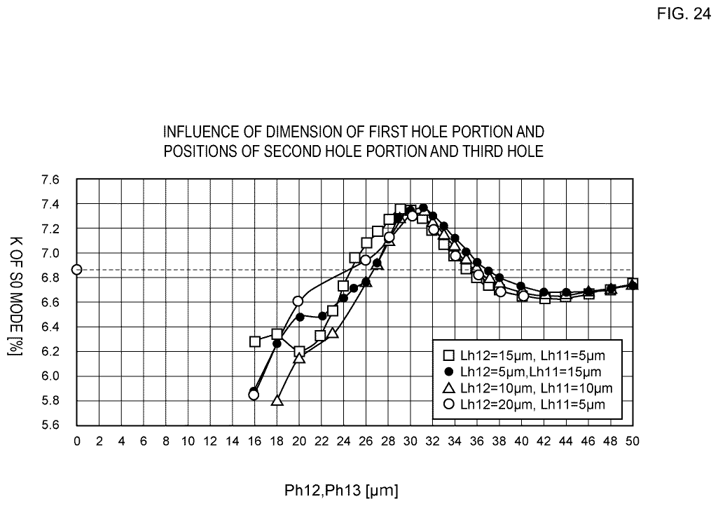

Next, the influence of the positions of the hole portions H72 and H73 in the second example will be described with reference to FIG. 24. FIG. 24 is a graph illustrating an influence of the dimension of the first hole portion and the positions of the second hole portion and the third hole portion. The horizontal axis in FIG. 24 indicates the hole portion gaps Ph12 and Ph13 (μm), and the vertical axis in FIG. 24 indicates the electromechanical coupling coefficient K (%) of the main mode S0.

FIG. 24 is a graph plotting a simulation result of the electromechanical coupling coefficient K of the main mode S0 corresponding to the hole portion gap Ph12 and the hole portion gap Ph13 when the first hole portion length Lh11 and the second hole portion length Lh12 of the hole portion H71 are changed in the second example.

Although the first hole portion length Lh11 and the second hole portion length Lh12 of the hole portion H71 is changed, the electromechanical coupling coefficient K of the main mode S0 indicates the same change with respect to the change in the hole portion gap Ph12 and the hole portion gap Ph13. The electromechanical coupling coefficient K of the main mode S0 is maximum when Ph12=Ph13=30 μm regardless of the dimension of the hole portion H71. In a range of 16 μm≤Ph12=Ph13<30 μm, the electromechanical coupling coefficient K of the main mode S0 monotonously increases. At 24 μm≤Ph12=Ph13, the electromechanical coupling coefficient K of the main mode S0 is larger than the electromechanical coupling coefficient K=6.87(%) of the main mode S0 in the comparative example. In a range of 30 μm≤Ph12=Ph13≤43 μm, the electromechanical coupling coefficient K of the main mode S0 monotonously decreases. At Ph12=Ph13≤38, the electromechanical coupling coefficient K of the main mode S0 is larger than the electromechanical coupling coefficient K=6.87(%) of the main mode S0 in the comparative example. In a range of 34 μm<Ph12=Ph13≤50 μm, the electromechanical coupling coefficient K of the main mode S0 monotonously increases. However, the change in the electromechanical coupling coefficient K of the main mode S0 in the range of 34 μm<Ph12=Ph13≤50 μm is smaller than the change in the electromechanical coupling coefficient K of the main mode S0 in the range of 30 μm≤Ph12=Ph13≤43 μm, and even at Ph12=Ph13=50 μm, the electromechanical coupling coefficient K of the main mode S0 is smaller than the electromechanical coupling coefficient K=6.87(%) of the main mode S0 in the comparative example.

In summary, the condition for the electromechanical coupling coefficient K of the main mode S0 to be increased over the configuration without the hole portions H71, H72, and H73 is that 24 μm≤Ph12=Ph13≤38 μm is established regardless of the dimension and the shape of the hole portion H71. In addition, the condition under which the electromechanical coupling coefficient K of the main mode S0 is maximum is that Ph12=Ph13=30+1 μm is established. Since Le1=120 μm, this means that the electromechanical coupling coefficient K of the main mode S0 is maximum when the hole portions H71, H72, and H73 are formed at positions that divide the first electrode length Le1 of the first excitation electrode into four equal parts in the Z′-axis direction.

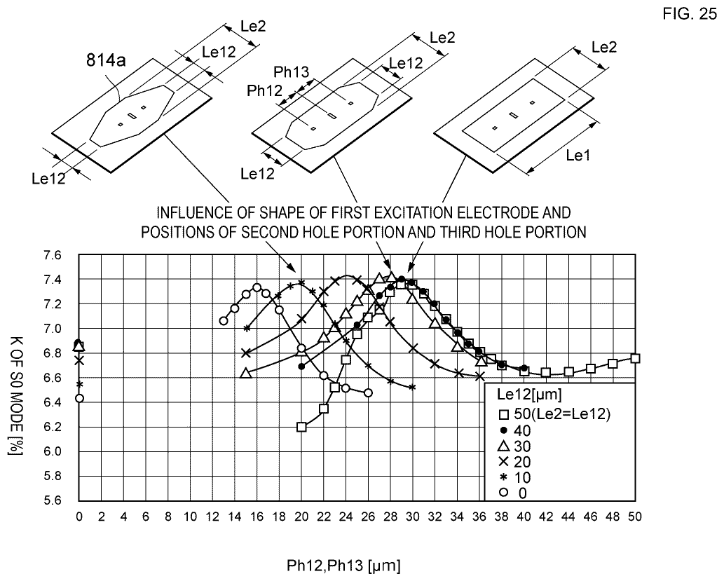

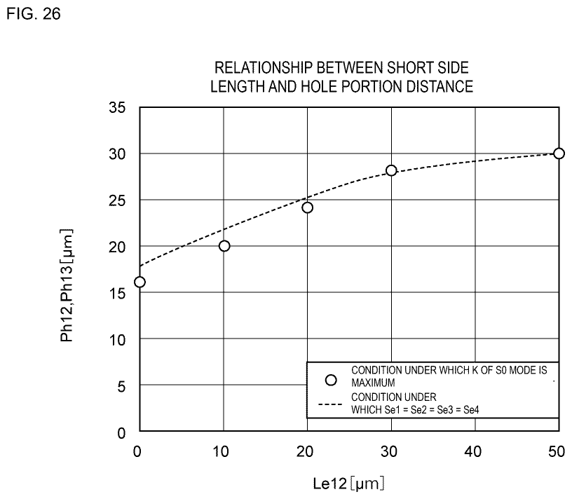

Next, the optimum positions of the hole portions H82 and H83 in the example based on the eighth embodiment will be described with reference to FIGS. 25 and 26. FIG. 25 is a graph illustrating the influence of the shape of the first excitation electrode and the positions of the second hole portion and the third hole portion. FIG. 26 is a graph illustrating a relationship between a short side length and a hole portion gap. The horizontal axis in FIG. 25 indicates the hole portion gaps Ph12 and Ph13 (μm), and the vertical axis in FIG. 25 indicates the electromechanical coupling coefficient K (%) of the main mode S0. The horizontal axis in FIG. 26 indicates the short side length Le12 (μm), and the vertical axis in FIG. 26 indicates the hole portion gaps Ph12 and Ph13 (μm).

FIG. 25 is a graph plotting a simulation result of the electromechanical coupling coefficient K of the main mode S0 when the hole portion gaps Ph12 and Ph13 (Ph12=Ph13) are changed in a case where the short side length Le12 is 50 μm, 40 μm, 30 μm, 20 μm, 10 μm, and 0 μm. The conditions other than the planar shape of the first excitation electrode and the hole portion gaps Ph12 and Ph13 are the same as those of the second example. When Le12=50 μm, the planar shape of the first excitation electrode is a rectangular shape. When Le12=0 μm, the planar shape of the first excitation electrode is a rhombus shape. When Le12=40 to 10 μm, the side of the first excitation electrode that is inclined with respect to the Z′-axis direction has a constant angle with respect to the Z′-axis direction.

The shape of the graph of the electromechanical coupling coefficient K of the main mode S0 is the same as the graph illustrated in FIG. 24 when the short side length Le12 is 50 μm, 40 μm, 30 μm, 20 μm, 10 μm, and 0 μm. However, the graph of the electromechanical coupling coefficient K of the main mode S0 slides in the horizontal axis direction according to the size of the short side length Le12. The smaller the short side length Le12, the smaller the hole portion gaps Ph12 and Ph13 (Ph12=Ph13) at which the electromechanical coupling coefficient K of the main mode S0 is maximum. The result is plotted in the graph of FIG. 26. The condition under which the electromechanical coupling coefficient K of the main mode S0 is maximum substantially coincides with the condition under which Se1=Se2=Se3=Se4. This means that the electromechanical coupling coefficient K of the main mode S0 is maximum when the hole portions H81, H82, and H83 are formed at positions that divide the electrode area Se of the first excitation electrode into four equal parts in the Z′-axis direction.

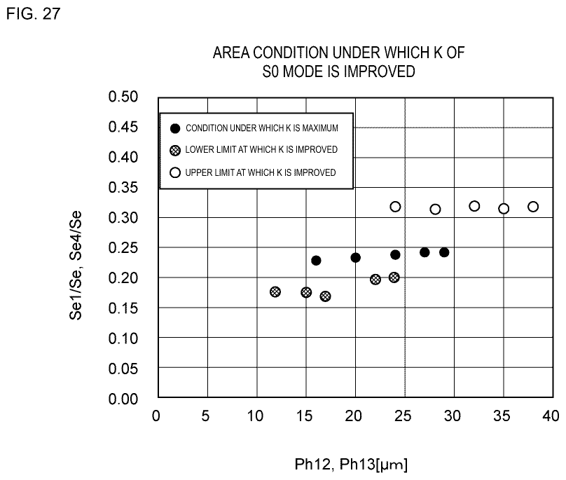

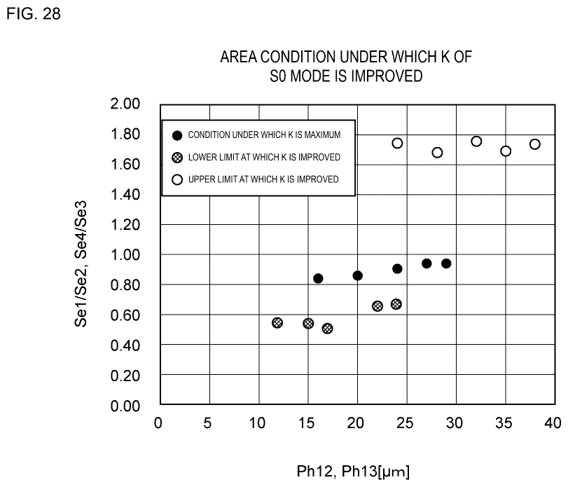

Next, the conditions under which the electromechanical coupling coefficient K of the main mode S0 is increased and is maximum in an example based on the eighth embodiment will be described with reference to FIGS. 27 and 28. FIG. 27 is a graph illustrating an area condition under which K of the S0 mode is increased. FIG. 28 is a graph illustrating an area condition under which K of the S0 mode is increased. The horizontal axes of FIGS. 27 and 28 indicate the hole portion gaps Ph12 and Ph13 (μm). The vertical axis in FIG. 27 indicates an area ratio Se1/Se of the area Se1 of the portion in the first excitation electrode on the negative direction side of the Z′-axis direction of the second hole portion with respect to the electrode area Se of the first excitation electrode. The vertical axis in FIG. 28 indicates the area ratio Se1/Se2 of the area Se1 of the portion of the first excitation electrode on the negative direction side of the Z′-axis direction of the second hole portion with respect to the area Se2 of the portion in the first excitation electrode on the positive direction side of the Z′-axis direction of the second hole portion and on the negative direction side of the Z′-axis direction of the first hole portion. The vertical axis in FIG. 27 is also the area ratio Se4/Se of the area Se4 of the portion in the first excitation electrode on the positive direction side of the Z′-axis direction of the third hole portion with respect to the electrode area Se of the first excitation electrode. In addition, the vertical axis in FIG. 28 also is the area ratio Se4/Se3 of the area Se4 of the portion of the first excitation electrode on the positive direction side of the Z′-axis direction of the third hole portion with respect to the area Se3 of the portion in the first excitation electrode on the positive direction side of the Z′-axis direction of the first hole portion and on the negative direction side of the Z′-axis direction of the third hole portion.

The plots in the graphs illustrated in FIGS. 27 and 28 are calculated based on the graph illustrated in FIG. 25. Specifically, when the short side length Le12 is 50 μm, 40 μm, 30 μm, 20 μm, 10 μm, and 0 μm, the upper limit and the lower limit of the hole portion gaps Ph12 and Ph13, at which the electromechanical coupling coefficient K of the main mode S0 is increased as compared with the comparative example without the first hole portion, the second hole portion, and the third hole portion, are read from FIG. 25. The area ratios Se1/Se and Se4/Se (Se1/Se=Se4/Se) in the hole portion gaps Ph12 and Ph13 are calculated and plotted on the graph in FIG. 27. In addition, the hole portion gaps Ph12 and Ph13 at which the electromechanical coupling coefficient K of the main mode S0 is maximum are read from FIG. 25, and the area ratios Se1/Se and Se4/Se in the hole portion gaps Ph12 and Ph13 are calculated and plotted on the graph in FIG. 27.

Similarly, the upper limit and lower limit of the hole portion gaps Ph12 and Ph13 at which the electromechanical coupling coefficient K of the main mode S0 is increased as compared with the comparative example are read from FIG. 25, and the area ratios Se1/Se2 and Se4/Se3 (Se1/Se2=Se4/Se3) in the hole portion gaps Ph12 and Ph13 are calculated and plotted on the graph in FIG. 28. In addition, the hole portion gaps Ph12 and Ph13 at which the electromechanical coupling coefficient K of the main mode S0 is maximum are read from FIG. 25, and the area ratios Se1/Se2 and Se4/Se3 in the hole portion gaps Ph12 and Ph13 are calculated and plotted on the graph in FIG. 28.

As illustrated in FIG. 27, the upper limits and lower limits of the area ratios Se1/Se and Se4/Se at which the electromechanical coupling coefficient K of the main mode S0 is increased as compared with the comparative example are substantially constant regardless of the size of the short side length Le12. In addition, the area ratios Se1/Se and Se4/Se at which the electromechanical coupling coefficient K of the main mode S0 is maximum are substantially constant regardless of the size of the short side length Le12. When the relationship of 0.18≤Se1/Se≤0.32 and 0.18≤Se4/Se≤0.32 is established, the electromechanical coupling coefficient K of the main mode S0 is increased as compared with the comparative example. In addition, when the relationship of Se1/Se=0.24+0.02 and Se4/Se=0.24=0.02 is established, the electromechanical coupling coefficient K of the main mode S0 is maximum.

As illustrated in FIG. 28, the upper limits and lower limits of the area ratios Se1/Se2 and Se4/Se3 at which the electromechanical coupling coefficient K of the main mode S0 is increased as compared with the comparative example are substantially constant regardless of the size of the short side length Le12. In addition, the area ratios Se1/Se2 and Se4/Se3 at which the electromechanical coupling coefficient K of the main mode S0 is maximum are substantially constant regardless of the size of the short side length Le12. When the relationship of 0.58≤Se1/Se2≤1.72 and 0.58≤Se4/Se3≤1.72 is established, the electromechanical coupling coefficient K of the main mode S0 is increased as compared with the comparative example. In addition, when the relationship of Se1/Se2=0.90±0.05 and Se4/Se3=0.90±0.05 is established, the electromechanical coupling coefficient K of the main mode S0 is maximum.

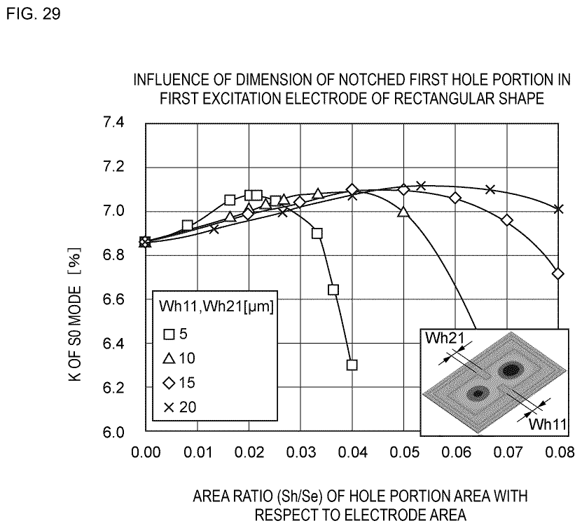

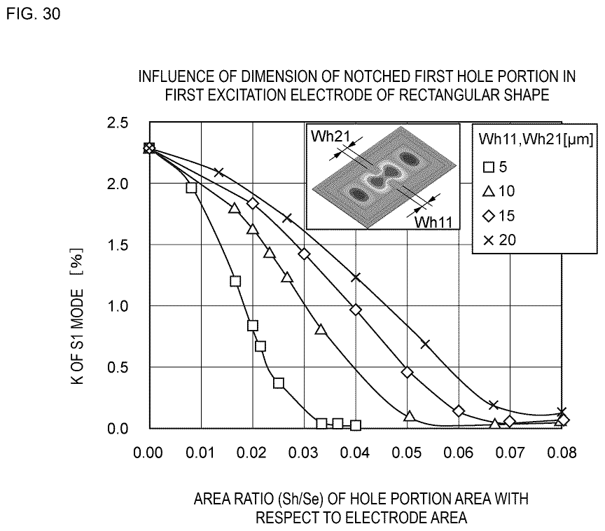

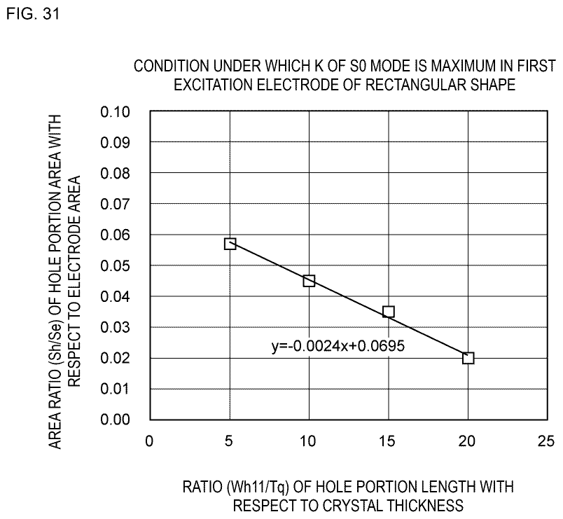

Next, the electromechanical coupling coefficient K according to the third example based on the sixth embodiment will be described with reference to FIGS. 29 to 31. FIG. 29 is a graph illustrating an influence of the dimension of the notched first hole portion in the first excitation electrode of a rectangular shape. FIG. 30 is a graph illustrating an influence of the dimension of the notched first hole portion in the first excitation electrode of a rectangular shape. FIG. 31 is a graph illustrating a condition under which K of the S0 mode is maximum in the first excitation electrode of a rectangular shape. The horizontal axes in FIGS. 29 and 30 indicate the area ratio Sh/Se of the hole portion area Sh of the first hole portion with respect to the electrode area Se of the first excitation electrode, the vertical axis in FIG. 29 indicates the electromechanical coupling coefficient K (%) of the main mode S0, and the vertical axis in FIG. 30 indicates the electromechanical coupling coefficient K (%) of the inharmonic mode S1Z. The horizontal axis of FIG. 31 indicates a ratio Wh11/Tq of the hole portion length Wh11 with respect to the crystal thickness Tq, and the vertical axis of FIG. 31 indicates the area ratio Har=Sh/Se of the hole portion area Sh of the first hole portion with respect to the electrode area Se of the first excitation electrode.

### Third Example

### Quartz Crystal Element

Cut-angles: AT cut
Planar shape: a square shape
Upper surface dimension: 140 μm×140 μm
Thickness Tq: 1 μm
Main mode S0: 1.45 GHz

### First Excitation Electrode

Material: Aluminum (Al) or Aluminum-Copper Alloy (AlCu)
First electrode length Le1: 120 μm (Le1/Tq=120)
Second electrode length Le2: 50 μm (Le2/Tq=50)
Electrode thickness Te: 0.05 μm

### First Hole Portion

Hole portion lengths Wh12 and Wh22: Parameter (Wh12=Wh22)
Hole portion lengths Wh11 and Wh21: Parameter (Wh11=Wh21)

FIG. 29 plots a simulation result of the electromechanical coupling coefficient K of the main mode S0 when the area ratio Har=Sh/Se is changed in a case where the hole portion lengths Wh11 and Wh21 (Wh11=Wh21) are 5 μm, 10 μm, 15 μm, and 20 μm. The change in the area ratio Har=Sh/Se is realized by changing the hole portion lengths Wh21 and Wh22.

The electromechanical coupling coefficient K of the main mode S0 indicates an upward convex graph within a range of 0<Har<0.08. The electromechanical coupling coefficient K of the main mode S0 is 6.87 when Har=0, but is approximately 7.1 at maximum when Wh11=Wh21=5 μm, 10 μm, 15 μm, and 20 μm. The smaller the hole portion lengths Wh11 and Wh21 (Wh11=Wh21), the smaller the area ratio Har=Sh/Se at which the electromechanical coupling coefficient K of the main mode S0 is maximum. The result is plotted in the graph of FIG. 31. As illustrated in the approximation expression in FIG. 31, the condition under which the electromechanical coupling coefficient K of the main mode S0 is maximum is that Har=−0.0024×(Wh11/Tq)+0.0695±0.01 is established.

FIG. 30 plots a simulation result of the electromechanical coupling coefficient K of the inharmonic mode S1Z when the area ratio Har=Sh/Se is changed in a case where the hole portion lengths Wh11 and Wh21 (Wh11=Wh21) are 5 μm, 10 μm, 15 μm, and 20 μm. The change in the area ratio Har=Sh/Se is realized by changing the hole portion lengths Wh21 and Wh22.

The electromechanical coupling coefficient K of the inharmonic mode S1Z indicates a downward convex graph within a range of 0<Har<0.08. The electromechanical coupling coefficient K of the inharmonic mode S1Z is 2.27 when Har=0, but is a minimum of 0.2 or less for all the cases of Wh11=Wh21=5 μm, 10 μm, 15 μm, and 20 μm and is a minimum of 0.1 or less when Wh11=Wh21=5 μm, 10 μm, and 15 μm. The smaller the hole portion lengths Wh11 and Wh21 (Wh11=Wh21), the smaller the area ratio Har=Sh/Se at which the electromechanical coupling coefficient K of the inharmonic mode S1Z is minimum.

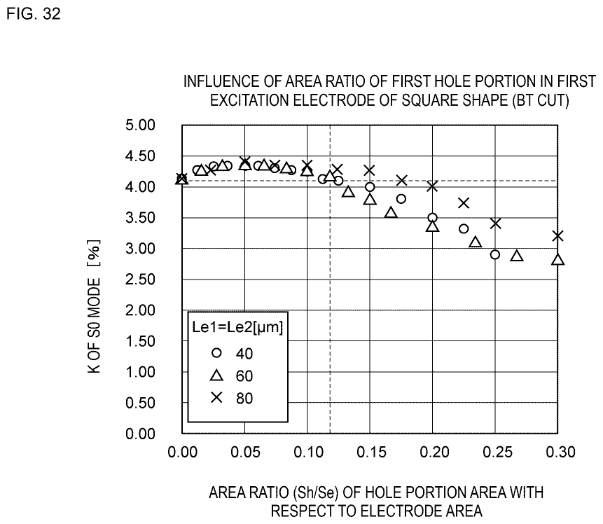

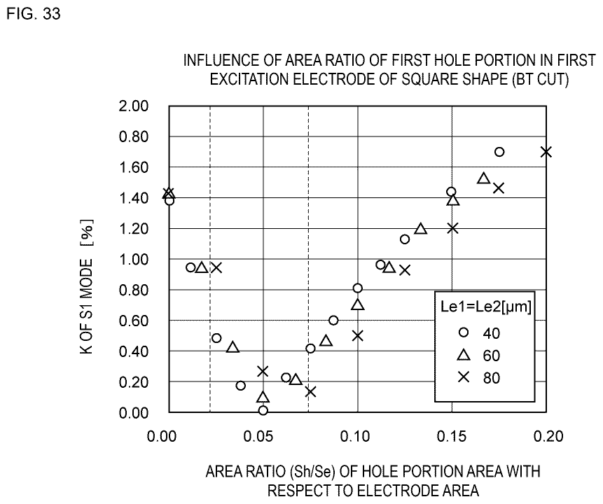

Next, a simulation result of the electromechanical coupling coefficient K when the quartz crystal element is a BT cut in the example based on the ninth embodiment will be described with reference to FIGS. 32 and 33. The example used for the simulation is the same as the first example except for the cut-angles of the quartz crystal element, the electrode length of the first excitation electrode, and the shape and the dimension of the first hole portion. FIGS. 32 and 33 is a graph illustrating an influence of the area ratio of the hole portion in the first excitation electrode of a square shape. The horizontal axes in FIGS. 32 and 33 indicate the area ratio Har=Sh/Se of the hole portion area Sh of the first hole portion with respect to the electrode area Se of the first excitation electrode, the vertical axis in FIG. 32 indicates the electromechanical coupling coefficient K of the main mode S0, and the vertical axis in FIG. 33 indicates the electromechanical coupling coefficient K of the inharmonic mode S1Z.

FIGS. 32 and 33 plot a simulation result of the electromechanical coupling coefficient K when the area ratio Har=Sh/Se is changed in a case where the electrode lengths Le1 and Le2 (Le1=Le2) of the first excitation electrode are 40 μm, 60 μm, and 80 μm. The area ratio Har=Sh/Se is realized by changing a radius R of the first hole portion.

As illustrated in FIG. 32, the electromechanical coupling coefficient K of the main mode S0 mode indicates an upward convex graph within a range of 0<Har<0.30. The electromechanical coupling coefficient K of the main mode S0 is approximately 4.10 when Har=0, but is approximately 4.40 at maximum. The electromechanical coupling coefficient K of the main mode S0 is increased as compared with the configuration without the first hole portion (Har=0) in a range of 0<Har≤0.125.

As illustrated in FIG. 33, the electromechanical coupling coefficient K of the inharmonic mode S1Z indicates a downward convex graph in a range of 0<Har<0.20. The electromechanical coupling coefficient K of the inharmonic mode S1Z is approximately 1.40 when Har=0, but is at least approximately 0.01 when Le1=Le2=40 μm, is approximately 0.10 at a minimum when Le1=Le2=60 μm, and is approximately 0.12 at a minimum when Le1=Le2=80 μm. The electromechanical coupling coefficient K of the inharmonic mode S1Z is decreased as compared with the configuration without a hole portion (Har=0) in a range of 0<Har≤0.15. The electromechanical coupling coefficient K of the inharmonic mode S1Z is further decreased in a range of 0.025≤Har≤0.075.

Some or all of the embodiments of the present disclosure will be appended below. The present disclosure is not limited to the following additional appendix.

<1> A piezoelectric resonator that includes: a piezoelectric element having a main surface that extends in a first direction and a second direction that intersects with the first direction and having a thickness in a third direction that intersects with the first direction and the second direction; and an excitation electrode on the main surface, the excitation electrode including a first hole portion that penetrates the excitation electrode along the third direction in a central portion of the excitation electrode in the first direction, wherein, when a dimension of the excitation electrode along the first direction is defined as Le1 and a dimension of the piezoelectric element along the third direction is defined as Tq, 45≤Le1/Tq≤120.

<2> The piezoelectric resonator according to <1>, in which 60≤Le1/Tq.

<3> The piezoelectric resonator according to <1> or <2>, in which the first hole portion is in a central portion of the excitation electrode in the second direction and is separated from an end portion of the excitation electrode extending in the first direction.

<4> The piezoelectric resonator according to <1> or <2>, in which the first hole portion is open in the second direction at the end portion of the excitation electrode extending in the first direction.

<5> The piezoelectric resonator according to any one of <1> to <4>, in which the first hole portion has a plurality of holes.

<6> The piezoelectric resonator according to any one of <1> to <5>, in which when a dimension of the excitation electrode along the second direction is defined as Le2, 10≤Le2/Tq≤45.

<7> The piezoelectric resonator according to any one of <1> to <5>, in which when a dimension of the excitation electrode along the second direction is defined as Le2, 45≤Le2/Tq≤120, and the first hole portion is in a central portion of the excitation electrode in the second direction.

<8> The piezoelectric resonator according to any one of <1> to <7>, in which the piezoelectric element is a quartz crystal element.

<9> The piezoelectric resonator according to <8>, in which the quartz crystal element is an AT cut, and the second direction is a direction parallel to an X-axis of a crystallographic axis of the quartz crystal element.

<10> The piezoelectric resonator according to <9>, in which when a dimension of the excitation electrode along the second direction is defined as Le2, and a ratio of an area of the first hole portion with respect to an area of the excitation electrode is defined as Har, Le1=Le2 and 0<Har≤0.23.

<11> The piezoelectric resonator according to <10>, in which Har=1.52×(Le2/Tq)^{-0.82}±0.01.

<12> The piezoelectric resonator according to any one of <9> to <11>, in which when a dimension of the excitation electrode along the second direction is defined as Le2, and a ratio of an area of the first hole portion with respect to an area of the excitation electrode is defined as Har, Le1=Le2 and 0<Har≤0.05.

<13> The piezoelectric resonator according to <12>, in which Har=1.05×(Le2/Tq)^{-0.92}±0.01.

<14> The piezoelectric resonator according to <9>, in which when a dimension of the excitation electrode along the second direction is defined as Le2, and a ratio of an area of the first hole portion with respect to an area of the excitation electrode is defined as Har, 0.5≤ Le2/Le1≤1.3, and Le2/Le1≠1.0, and 0<Har≤0.015×exp(2.53×Le2/Le1).

<15> The piezoelectric resonator according to <14>, in which Har=0.061×exp(3.25×Le2/Le1)×(Le2/Tq)^{-0.82}±0.01.

<16> The piezoelectric resonator according to <9>, in which when a dimension of the excitation electrode along the second direction is defined as Le2, and a ratio of an area of the first hole portion with respect to an area of the excitation electrode is defined as Har, 1.3<Le2/Le1≤2.0, and Le2/Le1≠1.0, and 0<Har≤0.704×exp(−1.07×Le2/Le1).

<17> The piezoelectric resonator according to <16>, in which Har=4.82×exp(−0.96×Le2/Le1)×(Le2/Tq)^{-0.82}±0.01.

<18> The piezoelectric resonator according to <9>, in which when a dimension of the excitation electrode along the second direction is defined as Le2, and a ratio of an area of the first hole portion with respect to an area of the excitation electrode is defined as Har, Le2/Le1≠1.0, and 0<Har≤0.02.

<19> The piezoelectric resonator according to <9>, in which 0.5≤Le2/Le1≤1.3, and Le2/Le1≠1.0, and Har=0.68×exp(0.48×Le2/Le1)×(Le2/Tq)^{-0.92}±0.01.

<20> The piezoelectric resonator according to <9>, in which 1.3<Le2/Le1≤2.0, and Har=0.44×exp(0.61×Le2/Le1)×(Le2/Tq)^{-0.92}±0.01.

<21> The piezoelectric resonator according to <8>, in which the quartz crystal element is a BT cut, and the second direction is a direction parallel to an X-axis of a crystallographic axis of the quartz crystal element.

<22> The piezoelectric resonator according to <21>, in which when a dimension of the excitation electrode along the second direction is defined as Le2, and a ratio of an area of the first hole portion with respect to an area of the excitation electrode is defined as Har, Le2=Le1, and 0<Har≤0.125.

<23> The piezoelectric resonator according to <21> or <22>, in which when a dimension of the excitation electrode along the second direction is defined as Le2, and a ratio of an area of the first hole portion with respect to an area of the excitation electrode is defined as Har, Le2=Le1, and 0.025≤Har≤0.075.

<24> The piezoelectric resonator according to any one of <1> to <9> and <14> to <21>, in which when a dimension of the excitation electrode along the second direction is defined as Le2, Le2/Le1≠1.0, and the first hole portion has a longitudinal direction along a direction orthogonal to a longitudinal direction of the excitation electrode.

<25> The piezoelectric resonator according to any one of <1> to <9> and <14> to <21>, in which when a dimension of the excitation electrode along the second direction is defined as Le2, Le2/Le1≠1.0, and the first hole portion has a longitudinal direction along a direction parallel to a longitudinal direction of the excitation electrode.

<26> The piezoelectric resonator according to any one of <1> to <25>, in which a second hole portion is further formed in a central portion in the first direction of a portion, which is on a negative direction side in the first direction with respect to the first hole portion, of the excitation electrode, and a third hole portion is further formed in a central portion in the first direction of a portion, which is on a positive direction side in the first direction with respect to the first hole portion, of the excitation electrode.

<27> The piezoelectric resonator according to <26>, in which when an area of the excitation electrode is defined as Se, an area of a portion in the excitation electrode on a negative direction side in the first direction of the second hole portion is defined as Se1, and an area of a portion in the excitation electrode on a positive direction side in the first direction of the third hole portion is defined as Se4, 0.18≤Se1/Se≤0.32, and 0.18≤Se4/Se≤0.32.

<28> The piezoelectric resonator according to <27>, in which Se1/Se=0.24+0.02, and Se4/Se=0.24=0.02.

<29> The piezoelectric resonator according to <26>, in which an area of a portion in the excitation electrode on a negative direction side in the first direction of the second hole portion is defined as Se1, an area of a portion in the excitation electrode on a positive direction side in the first direction of the second hole portion and on a negative direction side in the first direction of the first hole portion is defined as Se2, an area of a portion in the excitation electrode on a positive direction side in the first direction of the first hole portion and on a negative direction side in the first direction of the third hole portion is defined as Se3, and an area of a portion in the excitation electrode on a positive direction side in the first direction of the third hole portion is defined as Se4, 0.58≤Se1/Se2≤1.72, and 0.58≤Se4/Se3≤1.72.

<30> The piezoelectric resonator according to <29>, in which Se1/Se2=0.90±0.05, and Se4/Se3=0.90±0.05.

<31> The piezoelectric resonator according to <26>, in which the second hole portion is formed at a position that bisects an area of the portion, which is on the negative direction side in the first direction with respect to the first hole portion, of the excitation electrode in the first direction, and the third hole portion is formed at a position that bisects an area of the portion, on the positive direction side in the first direction with respect to the first hole portion, of the excitation electrode in the first direction.

<32> The piezoelectric resonator according to any one of <26> to <31>, in which an area of the second hole portion is smaller than an area of the first hole portion.

<33> The piezoelectric resonator according to any one of <1> to <32>, in which a thickness shear vibration mode is a main vibration mode of the piezoelectric resonator.

<34> The piezoelectric resonator according to any one of <1> to <33>, in which a main component of the excitation electrode is aluminum.

<35> A piezoelectric resonator unit that includes the piezoelectric resonator according to any one of <1> to <34>; a first lid member; and a second lid member that is bonded to the piezoelectric resonator or the first lid member and forms a space that houses a vibration portion of the piezoelectric resonator between the second lid member and the first lid member.

<36> A piezoelectric oscillator that includes the piezoelectric resonator unit according to <35>; a mounting substrate on which the piezoelectric resonator unit is mounted; and a lid that is bonded to the mounting substrate and forms a space that houses the piezoelectric resonator unit between the lid and the mounting substrate.

The embodiment according to the present disclosure is not limited to a quartz crystal resonator unit, but can be also applied to another piezoelectric resonator unit. As a piezoelectric element preferably used in the piezoelectric resonator unit according to the present embodiment, for example, a piezoelectric ceramic such as lead zirconate titanate (PZT) or aluminum nitride, or a piezoelectric single crystal such as lithium niobate or lithium tantalate, can be listed, but the present disclosure is not limited to these and can be selected as appropriate.

The embodiment according to the present disclosure is not particularly limited, but can be applied as appropriate to any device, which performs electromechanical energy conversion by a piezoelectric effect, such as a timing device, a sound generator, an oscillator, or a load sensor.

As described above, according to one aspect of the present disclosure, it is possible to provide a piezoelectric resonator, a piezoelectric resonator unit, and a piezoelectric oscillator that can improve the electromechanical coupling coefficient.

The embodiment described above is for easy understanding of the present disclosure, and is not for limiting and interpreting the present disclosure. The present disclosure can be changed/improved without deviating from the gist of the present disclosure, and the present disclosure also includes equivalents thereof. That is, any design change appropriately made by a person skilled in the art to the embodiment and/or modification example is included in the scope of the present disclosure as long as it has the features of the present disclosure. For example, each element and its disposition, material, condition, shape, size, or the like provided in the embodiment and/or modification example are not limited to those illustrated, and can be changed as appropriate. In addition, the embodiment and the modification example are examples, and it goes without saying that partial replacement or combination of the configurations illustrated in different embodiments and/or modification examples are possible and are also included in the scope of the disclosure as long as they include the features of the present disclosure.

### REFERENCE SIGNS LIST

100 CRYSTAL OSCILLATOR
1 QUARTZ CRYSTAL RESONATOR UNIT
10 QUARTZ CRYSTAL RESONATOR
11 QUARTZ CRYSTAL ELEMENT
11A VIBRATION PORTION
11B CAVITY
11C HOLDING PORTION
12a UPPER SURFACE
12b LOWER SURFACE
14a FIRST EXCITATION ELECTRODE
14b SECOND EXCITATION ELECTRODE
H1 HOLE PORTION
Le1 FIRST ELECTRODE LENGTH
Le2 SECOND ELECTRODE LENGTH
Lh11 FIRST HOLE PORTION LENGTH
Lh12 SECOND HOLE PORTION LENGTH
Te ELECTRODE THICKNESS
Lq CRYSTAL THICKNESS
214a to 914a FIRST EXCITATION ELECTRODE
H2 to H6, H71, H81, H9 HOLE PORTION
H61, H62 NOTCHED PORTION
H72, H73, H82, H83 HOLE PORTION

1. A piezoelectric resonator comprising:
a piezoelectric element having a main surface that extends in a first direction and a second direction that intersects with the first direction and having a thickness in a third direction that intersects with the first direction and the second direction; and
an excitation electrode on the main surface, the excitation electrode including a first hole portion that penetrates the excitation electrode along the third direction in a central portion of the excitation electrode in the first direction, wherein
when a dimension of the excitation electrode along the first direction is defined as Le1 and a dimension of the piezoelectric element along the third direction is defined as Tq, 45≤Le1/Tq≤120.

2. The piezoelectric resonator according to claim 1, wherein 60≤Le1/Tq.

3. The piezoelectric resonator according to claim 1, wherein the first hole portion is in a central portion of the excitation electrode in the second direction and is separated from an end portion of the excitation electrode extending in the first direction.

4. The piezoelectric resonator according to claim 1, wherein the first hole portion is open in the second direction at the end portion of the excitation electrode extending in the first direction.

5. The piezoelectric resonator according to claim 1, wherein the first hole portion includes a plurality of holes.

6. The piezoelectric resonator according to claim 1, wherein, when a dimension of the excitation electrode along the second direction is defined as Le2, 10≤Le2/Tq≤45.

7. The piezoelectric resonator according to claim 1, wherein, when a dimension of the excitation electrode along the second direction is defined as Le2, 45≤Le2/Tq≤120, and the first hole portion is in a central portion of the excitation electrode in the second direction.

8. The piezoelectric resonator according to claim 1, wherein the piezoelectric element is a quartz crystal element.

9. The piezoelectric resonator according to claim 8, wherein
the quartz crystal element is an AT cut, and
the second direction is a direction parallel to an X-axis of a crystallographic axis of the quartz crystal element.

10. The piezoelectric resonator according to claim 9, wherein, when a dimension of the excitation electrode along the second direction is defined as Le2, and a ratio of an area of the first hole portion with respect to an area of the excitation electrode is defined as Har, Le1=Le2 and 0<Har≤0.23.

11. The piezoelectric resonator according to claim 10, wherein Har=1.52×(Le2/Tq)^{-0.82}±0.01.

12. The piezoelectric resonator according to claim 9, wherein, when a dimension of the excitation electrode along the second direction is defined as Le2, and a ratio of an area of the first hole portion with respect to an area of the excitation electrode is defined as Har, Le1=Le2 and 0<Har≤0.05.

13. The piezoelectric resonator according to claim 12, wherein Har=1.05×(Le2/Tq)^{-0.92}±0.01.

14. The piezoelectric resonator according to claim 9, wherein, when a dimension of the excitation electrode along the second direction is defined as Le2, and a ratio of an area of the first hole portion with respect to an area of the excitation electrode is defined as Har, 0.5≤Le2/Le1≤1.3, Le2/Le1≠1.0, and 0<Har≤0.015×exp(2.53×Le2/Le1).

15. The piezoelectric resonator according to claim 14, wherein Har=0.061×exp(3.25×Le2/Le1)×(Le2/Tq)^{-0.82}±0.01.

16. The piezoelectric resonator according to claim 9, wherein, when a dimension of the excitation electrode along the second direction is defined as Le2, and a ratio of an area of the first hole portion with respect to an area of the excitation electrode is defined as Har, 1.3<Le2/Le1≤2.0, Le2/Le1≠1.0, and 0<Har≤0.704×exp(−1.07×Le2/Le1).

17. The piezoelectric resonator according to claim 16, wherein Har=4.82×exp(−0.96×Le2/Le1)×(Le2/Tq)^{-0.82}±0.01.

18. The piezoelectric resonator according to claim 9, wherein, when a dimension of the excitation electrode along the second direction is defined as Le2, and a ratio of an area of the first hole portion with respect to an area of the excitation electrode is defined as Har, Le2/Le1≠1.0 and 0<Har≤0.02.

19. The piezoelectric resonator according to claim 9, wherein 0.5≤Le2/Le1≤1.3, Le2/Le1≠1.0, and Har=0.68×exp(0.48×Le2/Le1)×(Le2/Tq)^{-0.92}±0.01.

20. The piezoelectric resonator according to claim 9, wherein 1.3<Le2/Le1≤2.0 and Har=0.44×exp(0.61×Le2/Le1)×(Le2/Tq)^{-0.92}±0.01.

21. The piezoelectric resonator according to claim 8, wherein
the quartz crystal element is a BT cut, and
the second direction is a direction parallel to an X-axis of a crystallographic axis of the quartz crystal element.

22. The piezoelectric resonator according to claim 21, wherein, when a dimension of the excitation electrode along the second direction is defined as Le2, and a ratio of an area of the first hole portion with respect to an area of the excitation electrode is defined as Har, Le2=Le1 and 0<Har≤0.125.

23. The piezoelectric resonator according to claim 21, wherein, when a dimension of the excitation electrode along the second direction is defined as Le2, and a ratio of an area of the first hole portion with respect to an area of the excitation electrode is defined as Har, Le2=Le1 and 0.025≤Har≤0.075.

24. The piezoelectric resonator according to claim 1, wherein, when a dimension of the excitation electrode along the second direction is defined as Le2, Le2/Le1≠1.0, and the first hole portion has a longitudinal direction along a direction orthogonal to a longitudinal direction of the excitation electrode.

25. The piezoelectric resonator according to claim 1, wherein, when a dimension of the excitation electrode along the second direction is defined as Le2, Le2/Le1≠1.0, and the first hole portion has a longitudinal direction along a direction parallel to a longitudinal direction of the excitation electrode.

26. The piezoelectric resonator according to claim 1, wherein the excitation electrode further includes
a second hole portion in a central portion in the first direction of a portion, which is on a negative direction side in the first direction with respect to the first hole portion, of the excitation electrode, and
a third hole portion in a central portion in the first direction of a portion, which is on a positive direction side in the first direction with respect to the first hole portion, of the excitation electrode.

27. The piezoelectric resonator according to claim 26, wherein, when an area of the excitation electrode is defined as Se, an area of the portion in the excitation electrode on the negative direction side in the first direction of the second hole portion is defined as Se1, and an area of the portion in the excitation electrode on the positive direction side in the first direction of the third hole portion is defined as Se4, 0.18≤Se1/Se≤0.32 and 0.18≤Se4/Se≤0.32.

28. The piezoelectric resonator according to claim 27, wherein Se1/Se=0.24=0.02 and Se4/Se=0.24=0.02.

29. The piezoelectric resonator according to claim 26, wherein
an area of the portion in the excitation electrode on the negative direction side in the first direction of the second hole portion is defined as Se1, an area of the portion in the excitation electrode on the positive direction side in the first direction of the second hole portion and on the negative direction side in the first direction of the first hole portion is defined as Se2, an area of the portion in the excitation electrode on the positive direction side in the first direction of the first hole portion and on the negative direction side in the first direction of the third hole portion is defined as Se3, and an area of the portion in the excitation electrode on the positive direction side in the first direction of the third hole portion is defined as Se4, 0.58≤Se1/Se2≤1.72 and 0.58≤Se4/Se3≤1.72.

30. The piezoelectric resonator according to claim 29, wherein Se1/Se2=0.90±0.05 and Se4/Se3=0.90±0.05.

31. The piezoelectric resonator according to claim 26, wherein
the second hole portion is at a position that bisects an area of the portion, which is on the negative direction side in the first direction with respect to the first hole portion, of the excitation electrode in the first direction, and
the third hole portion is at a position that bisects an area of the portion, on the positive direction side in the first direction with respect to the first hole portion, of the excitation electrode in the first direction.

32. The piezoelectric resonator according to claim 26, wherein an area of the second hole portion is smaller than an area of the first hole portion.

33. The piezoelectric resonator according to claim 1, wherein a thickness shear vibration mode is a main vibration mode of the piezoelectric resonator.

34. The piezoelectric resonator according to claim 1, wherein a main component of the excitation electrode is aluminum.

35. A piezoelectric resonator unit comprising:
the piezoelectric resonator according to claim 1;
a first lid member; and
a second lid member that is bonded to the piezoelectric resonator or the first lid member so as to form a space that houses a vibration portion of the piezoelectric resonator between the second lid member and the first lid member.

36. A piezoelectric oscillator comprising:
the piezoelectric resonator unit according to claim 35;
a mounting substrate on which the piezoelectric resonator unit is mounted; and
a lid that bonded to the mounting substrate and forms a space that houses the piezoelectric resonator unit between the lid and the mounting substrate.
